(19) United States
(12) Patent Application Publication
(10) Pub. No.: US 2017/0018591 A1
(43) Pub. Date: Jan. 19, 2017

(54) IMAGE PICKUP DEVICE AND METHOD FOR MANUFACTURING THE SAME

(71) Applicant: Renesas Electronics Corporation, Tokyo (JP)

(72) Inventor: Tadashi YAMAGUCHI, Tokyo (JP)

(73) Assignee: Renesas Electronics Corporation, Tokyo (JP)

(21) Appl. No.: 15/168,371

(22) Filed: May 31, 2016

(30) Foreign Application Priority Data
Jul. 16, 2015 (JP) 2015-142027

(51) Int. Cl. H01L 27/146

(52) U.S. Cl. CPC H01L 27/14638; H01L 27/14643; H01L 27/14614; H01L 27/14605; H01L 27/14627; H01L 27/14689

(57) ABSTRACT

An image pickup device capable of completely transmit charges generated at a photodiode to a floating diffusion region is provided. In a pixel region, a plurality of fin-like structures are so formed as to loin a photodiode formation region with the floating diffusion region. In the fin-like structure, a depth from a surface of a P type well to a predetermined position of depth is defined as a “height.” Having the height and a width, the fin-like structure extends in a direction intersecting a direction in which a gate electrode extends. The gate electrode of a transfer transistor is so formed as to cover opposing side surfaces and an upper surface of each fin-like structure.

### CROSS-REFERENCE TO RELATED APPLICATIONS

The disclosure of Japanese Patent Application No. 2015-142027 filed on Jul. 16, 2015 including the specification, drawings and abstract is incorporated herein by reference in its entirety.

### BACKGROUND

The present invention relates to an image pickup device and a method for manufacturing the same, which is suitably applicable, for example, to an image pickup device including a transfer transistor which transmits generated electric charges.

To a digital camera etc., for example, an image pickup device having a CMOS (Complementary Metal Oxide Semiconductor) image sensor is applied. In the image pickup device, there is formed a photodiode for converting incident light to electric charges. Specifically, in the case of a single-lens reflex camera, for taking pictures with fine effects of light and shade, the photodiode is required to increase the number (capacity) of saturation electrons.

To increase the number of saturation electrons, for example, there are employed a method of raising impurity concentration of the photodiode, a method of increasing an area to be occupied by the photodiode, and a method of forming a well region, where the photodiode is formed, at a deeper position. In Patent Documents 1 and 2, such types of image pickup devices are disclosed.

The electric charge generated at the photodiode is transmitted to a floating diffusion region by a transfer transistor. The transmitted electric charge is converted to an electric signal by an amplifying transistor and is output as an image signal.

### PATENT DOCUMENTS

[Patent Document 1]

Japanese Unexamined Patent Publication No. 2000-31451

[Patent Document 2]

Japanese Unexamined Patent Publication No. 2005-332925

[Patent Document 3]

Japanese Unexamined Patent Publication No. 2011-54718

### SUMMARY

As described above, in the image pickup device, the charges generated at the photodiode are transmitted to the floating diffusion region by the transfer transistor. On this occasion, the charges are transmitted to the floating diffusion region through a channel region formed immediately below a gate electrode of the transfer transistor. Generally, as the gate electrode of the transfer transistor, a planar type gate electrode is formed.

On the other hand, in an image pickup device having a large number of saturation electrons, incomplete transfer of the charges generated at the photodiode causes a transfer error. The transfer error of the charges may bring about particular errors such as a retained image. Therefore, in the image pickup device, complete transfer of the charges generated at the photodiode to the floating diffusion region is asked for. However, in the planar type gate electrode, it is becoming difficult to transmit the charges completely.

Other objects and the novel features will become apparent from the description of this specification and the attached drawings.

An image pickup device according to one embodiment includes: an element formation region having a pixel region and a peripheral circuit region; a gate electrode having a transfer gate electrode of a transfer transistor; a photoelectric conversion part; a floating diffusion region; and a fin-like structure having a pixel fin-like structure formed in the pixel region. The pixel fin-like structure includes a pixel fin-like structure which is formed in the pixel region, which extends having a height and a width, and which joins the photoelectric conversion part with the floating diffusion region. The above height is defined by a depth from a surface of a semiconductor substrate to a position of depth deeper than the surface, and the above pixel fin-like structure extends in a direction intersecting a direction in which the transfer gate electrode extends. The transfer gate electrode is so formed as to cover a surface of the pixel fin-like structure.

A method for manufacturing an image pickup device according to another embodiment includes the following steps. An element formation region including a pixel region is formed. A gate electrode including a transfer gate electrode is formed. A photoelectric conversion part is formed. A floating diffusion region is formed. In the step of forming the pixel region, openings are formed being spaced from one another in a region where the transfer gate electrode is formed in the pixel region. The opening is filled with an insulation film. By removing a portion of the insulation film ranging from the surface thereof to a position of depth shallower than a bottom of the opening, a fin-like structure which extends having a width and a height and which joins a first region with a second region is formed. The above width is defined by a spacing and the above height is defined a depth. Further, the fin-like structure extends in a direction intersecting a direction in which the transfer gate electrode is to extend. In the step of forming the transfer gate electrode, the transfer gate electrode is so formed as to cover the surface of the fin-like structure.

According to the image pickup device of one embodiment, it becomes possible to completely transmit charges generated in the photoelectric conversion part to the floating diffusion region.

According to another embodiment, it becomes possible to manufacture an image pickup device which can completely transmit charges generated in the photoelectric conversion part to the floating diffusion region.

### BRIEF DESCRIPTION OF THE DRAWINGS

FIG. 1 is a block diagram of an image pickup device according to each embodiment;

FIG. 2 is a plan view showing one example of an arrangement pattern of a pixel region and a peripheral circuit region of the image pickup device according to each embodiment;

FIG. 3 is an equivalent circuit diagram of pixels of the image pickup device according to each embodiment;

FIG. 4 is a partial plan view showing a pixel region and a peripheral circuit region in an image pickup device according to First Embodiment;

FIG. 5 is a sectional view taken along line V-V of FIG. 4 according to First Embodiment;

FIG. 6 is a perspective, sectional view taken along line VI-VI of FIG. 4 according to First Embodiment;

FIG. 7 is a sectional view taken along line VII-VII of FIG. 6 for explaining a configuration of a gate electrode of a transfer transistor according to First Embodiment;

FIG. 8 is a sectional view taken along line VIII-VIII of FIG. 6 for explaining the configuration of the gate electrode of the transfer transistor according to First Embodiment;

FIG. 9 is a sectional view taken along line IX-IX of FIG. 6 for explaining the configuration of the gate electrode of the transfer transistor according to First Embodiment;

FIG. 10 is a sectional view showing one step of a method for manufacturing the image pickup device according to First Embodiment;

FIG. 11 is a perspective, partial sectional view showing a trench in a region where the gate electrode of the transfer transistor is arranged in the step shown in FIG. 10 according to First Embodiment;

FIG. 12 is a sectional view showing a step performed after the step shown in FIG. 10 according to First embodiment;

FIG. 13 is a perspective, partial sectional view showing a separating insulation film formed in a trench of a region where the gate electrode of the transfer transistor is arranged in the step shown in FIG. 12 according to First Embodiment;

FIG. 14 is a perspective, partial sectional view showing a step performed after the steps shown in FIGS. 12 and 13 according to First Embodiment;

FIG. 15 is a sectional view showing a step performed after the step shown in FIG. 14 according to First Embodiment;

FIG. 16 is a sectional view showing a step performed after the step shown in FIG. 15 according to First Embodiment;

FIG. 17 is a perspective, partial sectional view showing the gate electrode of the transfer transistor in the step shown in FIG. 16 according to First Embodiment;

FIG. 18 is a sectional view showing a step performed after the steps shown in FIGS. 16 and 17 according to First Embodiment;

FIG. 19 is a sectional view showing a step performed after the step shown in FIG. 18 according to First Embodiment;

FIG. 20 is a sectional view showing a step performed after the step shown in FIG. 19 according to First Embodiment;

FIG. 21 is a sectional view showing a step performed after the step shown in FIG. 20 according to First Embodiment;

FIG. 22 is a sectional view showing a step performed after the step shown in FIG. 21 according to First Embodiment;

FIG. 23 is a sectional view showing a step performed after the step shown in FIG. 22 according to First Embodiment;

FIG. 24 is a sectional view showing a step performed after the step shown in FIG. 23 according to First Embodiment;

FIG. 25 is a sectional view showing a step performed after the step shown in FIG. 24 according to First Embodiment;

FIG. 26 is a sectional view showing a step performed after the step shown in FIG. 25 according to First Embodiment;

FIG. 27 is a sectional view showing a step performed after the step shown in FIG. 26 according to First Embodiment;

FIG. 28 is a sectional view showing a step performed after the step shown in FIG. 27 according to First Embodiment;

FIG. 29 is a sectional view showing a step performed after the step shown in FIG. 28 according to First Embodiment;

FIG. 30 is a plan view showing an example of an arrangement pattern of a pixel region and a peripheral circuit region of an image pickup device according to a comparative example;

FIG. 31 is a sectional view taken along line XXXI-XXXI of FIG. 30;

FIG. 32 is a perspective, partial sectional view for explaining a configuration of a gate electrode of a transfer transistor in the image pickup device according to the comparative example;

FIG. 33 is a perspective view for explaining a channel region formed by the transfer transistor and a channel region formed by a transfer transistor of the comparative example according to First Embodiment;

FIG. 34 is a sectional view showing one step of a method for manufacturing an image pickup device of a modification according to First Embodiment;

FIG. 35 is a sectional view showing a step performed after the step shown in FIG. 34 according to First Embodiment;

FIG. 36 is a sectional view of an image pickup device according to Second Embodiment;

FIG. 37 is a perspective, partial sectional view for explaining a configuration of a gate electrode of a transfer transistor in a red pixel region according to Second Embodiment;

FIG. 38 is a sectional view taken along line XXXVIII-XXXVIII of FIG. 37 for explaining the gate electrode of the transfer transistor according to Second Embodiment;

FIG. 39 is a sectional view taken along line XXXIX-XXXIX of FIG. 37 for explaining the gate electrode of the transfer transistor according to Second Embodiment;

FIG. 40 is a sectional view taken along line XL-XL of FIG. 37 for explaining the gate electrode of the transfer transistor according to Second Embodiment;

FIG. 41 is a perspective, partial sectional view for explaining a configuration of the gate electrode of the transfer transistor in a green pixel region according to Second Embodiment;

FIG. 42 is a sectional view taken along line XLII-XLII of FIG. 41 for explaining a configuration of the gate electrode of the transfer transistor according to Second Embodiment;

FIG. 43 is a sectional view taken along line XLIII-XLIII of FIG. 41 for explaining the configuration of the gate electrode of the transfer transistor according to Second Embodiment;

FIG. 44 is a sectional view taken along line XLIV-XLIV of FIG. 41 for explaining the configuration of the gate electrode of the transfer transistor according to Second Embodiment;

FIG. 45 is a perspective, partial sectional view for explaining a configuration of the gate electrode of the transfer transistor in a blue pixel region according to Second Embodiment;

FIG. 46 is a sectional view taken along line XLVI-XLVI of FIG. 45 for explaining the configuration of the gate electrode of the transfer transistor according to Second Embodiment;

FIG. 47 is a sectional view taken along line XLVII-XLVII of FIG. 45 for explaining the configuration of the gate electrode of the transfer transistor according to Second Embodiment;

FIG. 48 is a sectional view taken along line XLVIII-XLVIII of FIG. 45 for explaining the configuration of the gate electrode of the transfer transistor according to Second Embodiment;

FIG. 49 is a perspective, partial sectional view of a red pixel region showing one step of a method for manufacturing the image pickup device according to Second Embodiment;

FIG. 50 is a perspective, partial sectional view of a green pixel region showing another one step of the method for manufacturing the image pickup device according to Second Embodiment;

FIG. 51 is a perspective, partial sectional view of a blue pixel region showing still another one step of the method for manufacturing the image pickup device according to Second Embodiment;

FIG. 52 is a sectional view, including the red pixel region, showing a step performed after the steps shown in FIGS. 49 to 51 according to Second Embodiment;

FIG. 53 is a perspective, partial sectional view showing the gate electrode of the transfer transistor in the red pixel region of the step shown in FIG. 52 according to Second Embodiment;

FIG. 54 is a sectional view, including the green pixel region, showing a step performed after the steps shown in FIGS. 49 to 51 according to Second Embodiment;

FIG. 55 is a perspective, partial sectional view showing the gate electrode of the transfer transistor in the green pixel region of the step shown in FIG. 54 according to Second Embodiment;

FIG. 56 is a sectional view, including the blue pixel region, showing a step performed after the steps shown in FIGS. 49 to 51 according to Second Embodiment;

FIG. 57 is a perspective, partial sectional view showing the gate electrode of the transfer transistor in the blue pixel region of the step shown in FIG. 56 according to Second Embodiment;

FIG. 58 is a perspective, partial sectional view showing the gate electrode of the transfer transistor of the red pixel region in the image pickup device of a modification according to Second Embodiment;

FIG. 59 is a perspective, partial sectional view showing the gate electrode of the transfer transistor of the green pixel region in the image pickup device of the modification according to Second Embodiment;

FIG. 60 is a perspective, partial sectional view showing the gate electrode of the transfer transistor of the blue pixel region in the image pickup device of the modification according to Second Embodiment;

FIG. 61 is a partial plan view showing a pixel region and a peripheral circuit region in an image pickup device according to Third Embodiment;

FIG. 62 is a sectional view taken along line LXII-LXII of FIG. 61 according to Third Embodiment;

FIG. 63 is a perspective, partial sectional view showing a gate electrode of a logic transistor in the image pickup device according to Third Embodiment; and

FIG. 64 is a perspective, partial sectional view showing a gate electrode of a pixel transistor in the image pickup device of a modification according to Third Embodiment.

### DETAILED DESCRIPTION

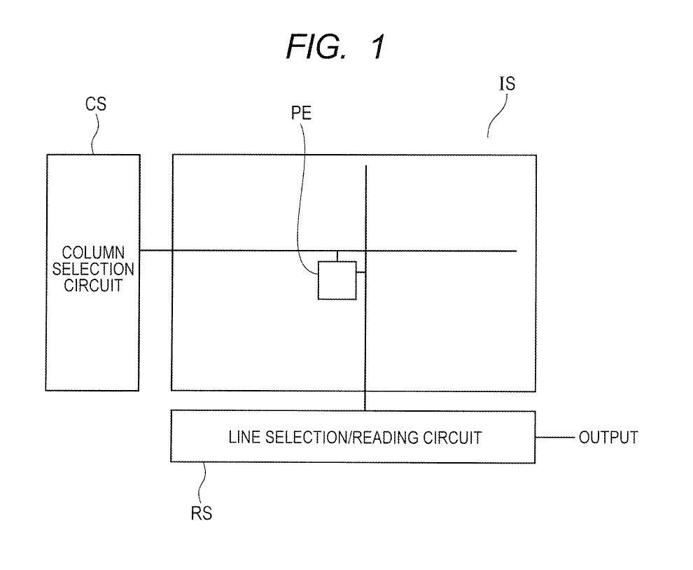

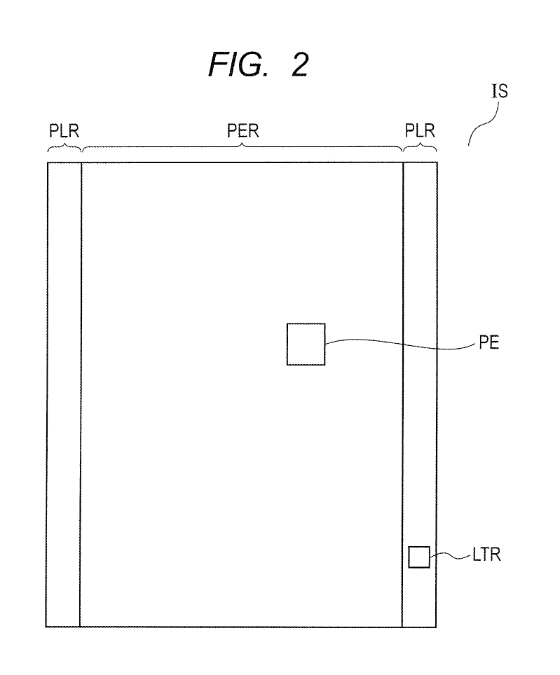

First, an overall configuration of the image pickup device including circuits will be explained. The image pickup device is comprised of a plurality of pixel parts arranged in a matrix shape. As shown in FIG. 1, a column selection circuit CS and a line selection/reading circuit RS are coupled to a pixel part PE. Also, FIG. 1 shows one pixel part PE of the pixel parts for simplifying the drawing. As shown in FIG. 2, the pixel parts containing the one pixel part PE are formed in a pixel region PER. The column selection circuit CS and the line selection/reading circuit RS are formed in a peripheral circuit region PLR.

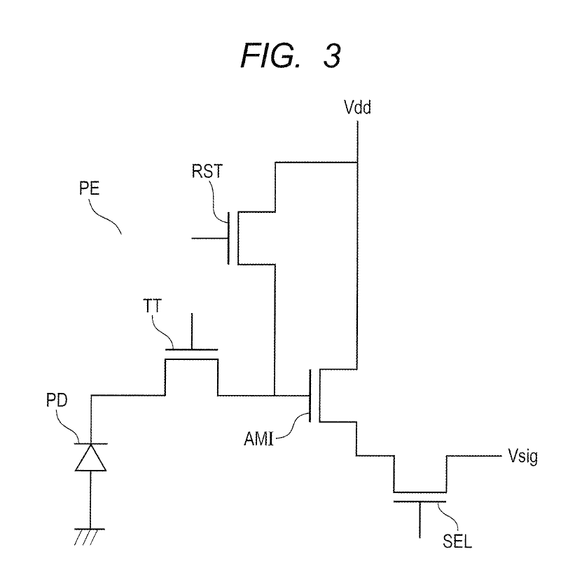

In the pixel part PE, as shown in FIG. 3, there are provided a photodiode PD, a transfer transistor TT, an amplifying transistor AMI, a selection transistor SEL, and a resetting transistor RSTI. In the photodiode PD, light from an object is accumulated as electric charges. The transfer transistor TT transmits the charge to a floating diffusion region (not shown). The resetting transistor RST resets charges in the floating diffusion region before the above charge is transmitted to the floating diffusion region.

The charge transmitted to the floating diffusion region is input into a gate electrode of the amplifying transistor AMI, and is converted to a voltage (Vdd) and amplified. When the signal which chooses a specific line of the pixel part is input to the gate electrode of the selection transistor SEL, the signal converted to the voltage is read as an image signal (Vsig). Hereafter, the configuration of the image pickup device according to each embodiment will be explained specifically.

### First Embodiment

In First Embodiment, there will be given an explanation of one example of an image pickup device where the gate electrode of the transfer transistor is of a fin type, and the gate electrode of the logic transistor as a peripheral transistor is of a planar type.

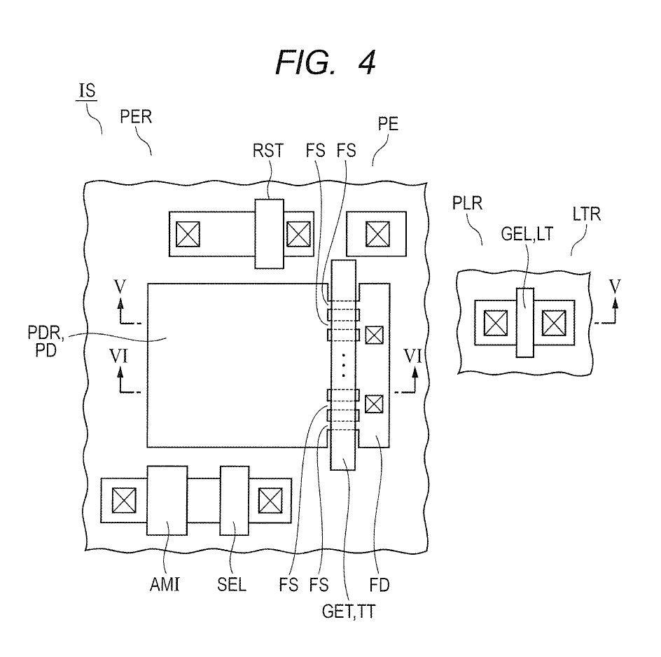

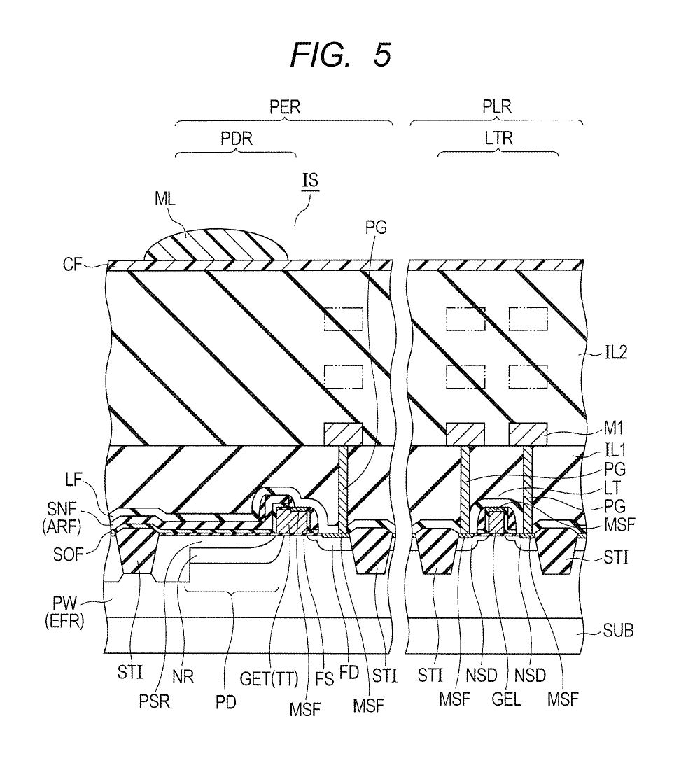

As shown in FIGS. 4 and 5, by forming an insulation film in a trench formed in a predetermined region over the semiconductor substrate SUB, a separating insulation film STI is formed. The pixel region PER and the peripheral circuit region PLR are prescribed as element formation regions by the separating insulation film STI.

The gate electrode GET of the transfer transistor TT is formed across the pixel region PER (P type well PW). A photodiode formation region PDR is located in a portion of the P type well PW located on one side across the gate electrode GET. The floating diffusion region FD is formed in a portion of the P type well PW located on the other side across the gate electrode GET. As a fin-type transistor, though described later, the gate electrode GET is formed so that it may cover a surface of a fin-like structure FS containing a portion of the P type well PW. Further, there is Patent Document 3 in which a commonly used fin-type transistor is disclosed.

A photodiode PD is formed in the photodiode formation region PDR. The photodiode PD includes an N type impurity region NR. Over the N type impurity region NR, a P type impurity region PSR is formed. A silicon oxide film SOF and an antireflection coating film ARF are so formed as to cover the photodiode formation region PDR. A metal silicide film NSF is formed over a surface of the floating diffusion region FD and part of a surface of the gate electrode GET. Also, in the pixel region PER, the amplifying transistor AMI, the selection transistor SEL, and the resetting transistor RST are formed around the photodiode formation region PDR.

In the peripheral circuit region PLR, for example, a logic transistor formation region LTR is prescribed. In the logic transistor formation region LTR, a logic transistor LT is formed. A gate electrode GEL of the logic transistor LT is formed across the logic transistor formation region LTR. There are formed source/drain regions NSD in a portion of the logic transistor formation region LTR located on one side across the gate electrode GEL and in a portion of the logic transistor formation region LTR located on the other side across the gate electrode GEL, respectively. The metal silicide films NSF are formed over the surface of the source/drain regions NSD and the surface of the gate electrode GEL.

A liner film LF is so formed as to cover the antireflection coating film ARF, the gate electrode GET, the gate electrode GEL, etc. A first interlayer insulation film IL1 is so formed as to cover the liner film LF. In the pixel region PER, a contact plug PG coupled to the floating diffusion region FD is so formed as to pass through the first interlayer insulation film IL1. In the peripheral circuit region PLR, contact plugs PG coupled to the source/drain regions NSD are formed, respectively.

Over the first interlayer insulation film IL1, a first wiring M1 electrically coupled to the contact plug PG is formed. A second interlayer insulation film IL2 is so formed as to cover the first wiring M1. The second interlayer insulation film IL2 contains a plurality of layers. Between the layers, there are formed a plurality of wirings (two-dot chain line). A color filter CF is formed over the second interlayer insulation film IL2, and a micro-lens ML is formed over the color filter CF.

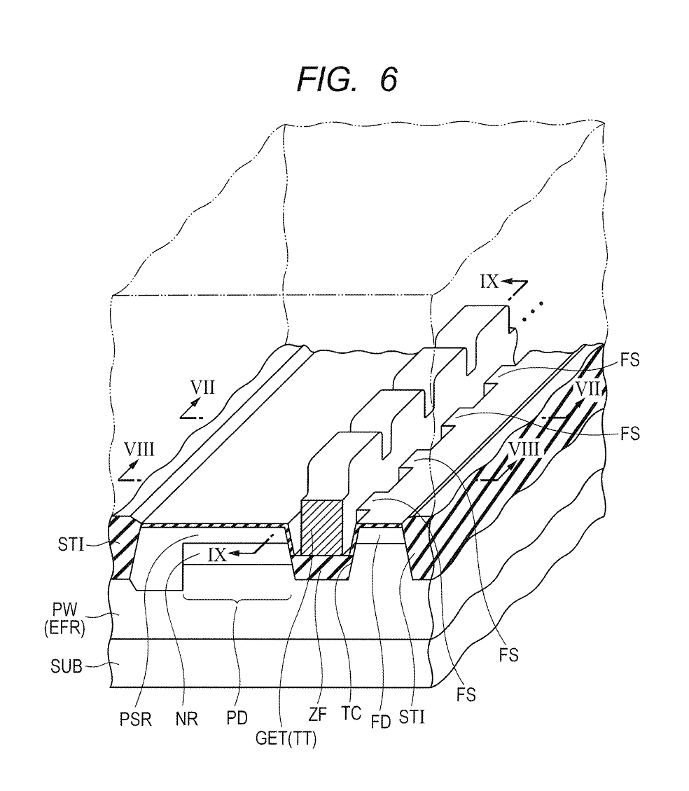

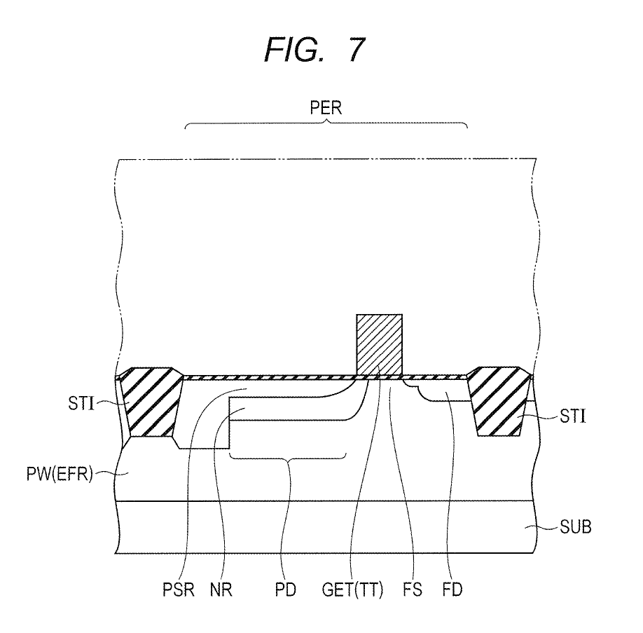

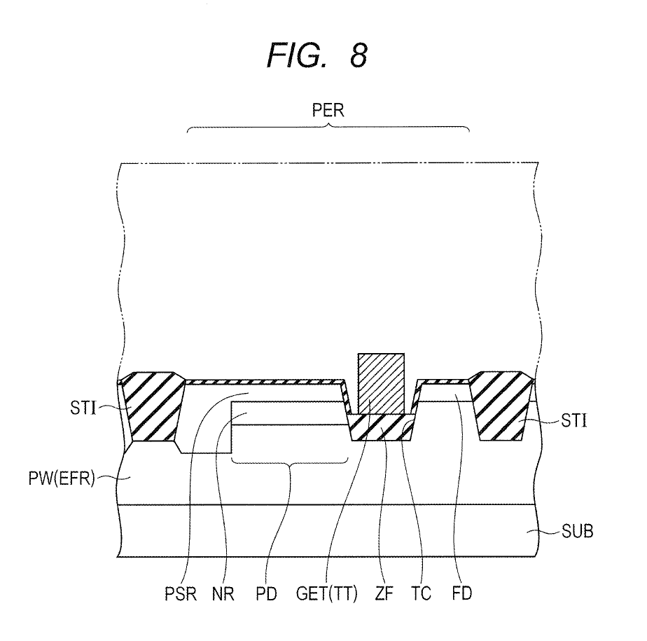

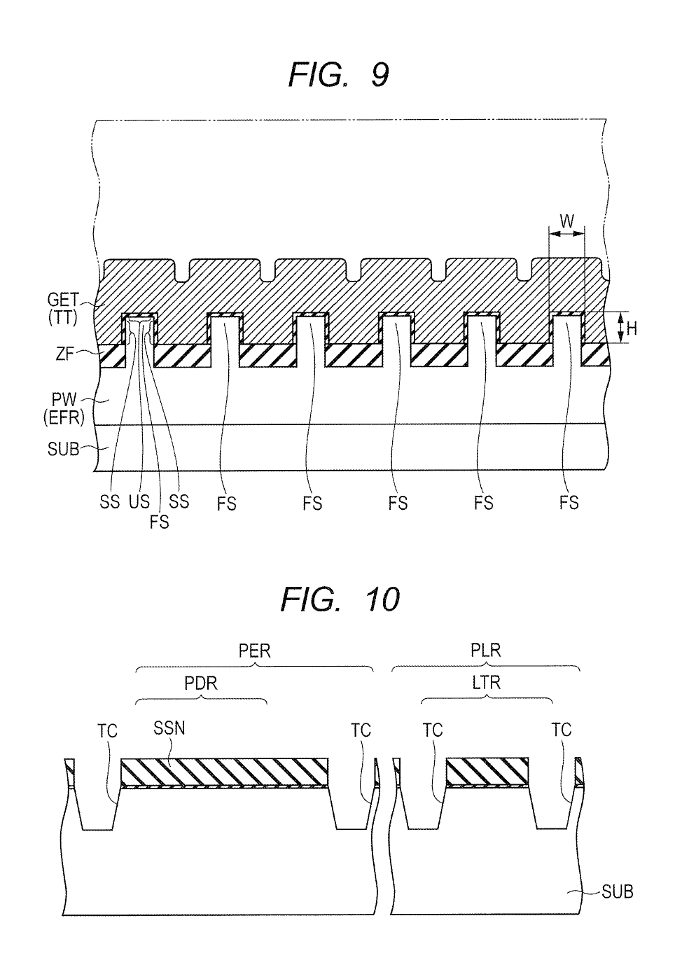

Next, a configuration of the fin type transfer transistor TT will be described. As shown in FIGS. 6 to 9, in the pixel region PER, so as to join the photodiode formation region PDR with the floating diffusion region FD, a plurality of pillar-shaped or wall-shaped fin-like structures FS are formed by portions of the P type well PW. The fin-like structures FS are arranged being spaced from one another in a direction in which the gate electrode GET is to extend.

In each fin-like structure FS, a depth from a surface of the P type well PW (semiconductor substrate SUB) to a predetermined position of depth is defined as a height H. Having the height H and a width N, the fin-like structure FS extends in a direction intersecting a direction in which the gate electrode GET extends. The gate electrode GET of the transfer transistor TT is so formed as to cover opposing side surfaces SS and an upper surface US of each fin-like structure FS. A channel region is formed in each fin-like structure FS by applying a voltage of a threshold value or greater to the gate electrode GET.

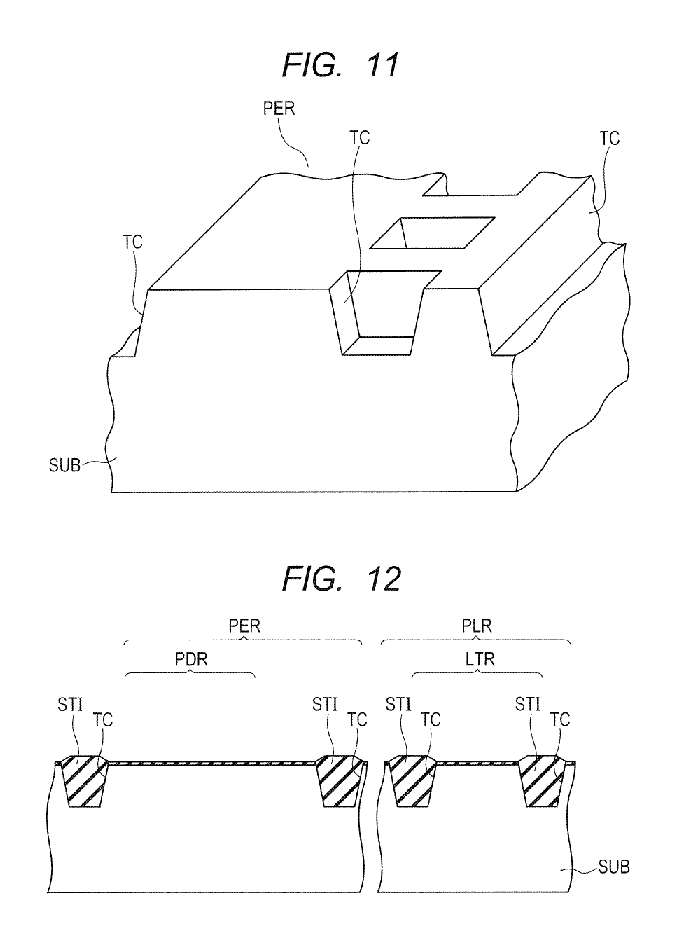

Next, an example of a method for manufacturing the image pickup device will be explained. First, as shown in FIG. 10, using a silicon nitride film SSN etc. as an etching mask, by applying an etching treatment to the semiconductor substrate SUB, a trench TC of a predetermined depth is formed. At this time, as shown in FIG. 11, in the pixel region PER, in which the gate electrode of the transfer transistor is formed, a plurality of trenches TC are formed spaced from one another in a direction in which the gate electrode extends. Also, in FIG. 11, in order to show the trenches TC clearly, the silicon nitride film SSN etc. are omitted.

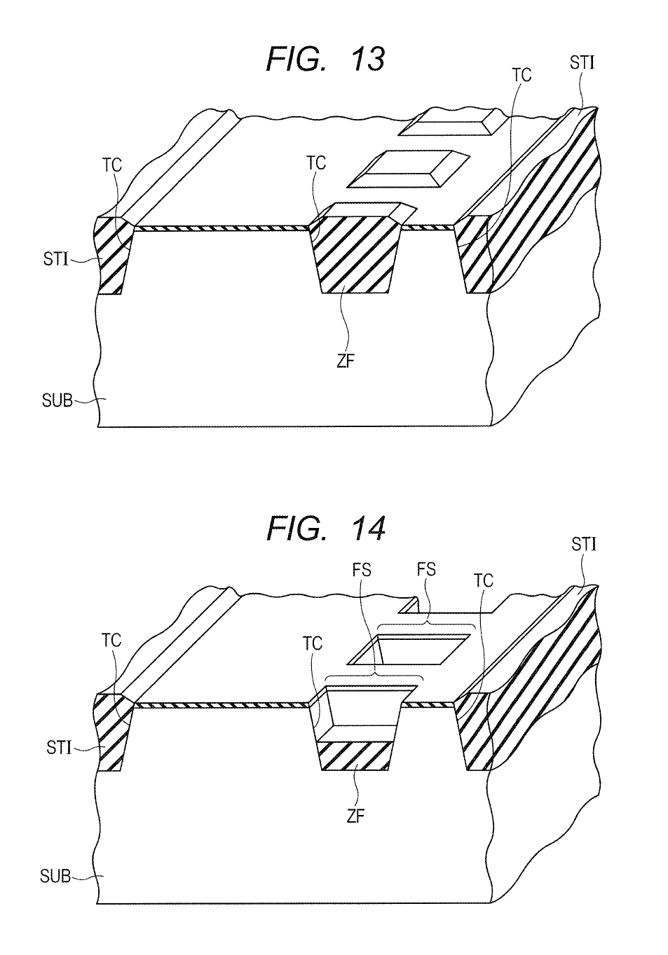

Next, a silicon oxide film (not shown) is formed so that the trench TC may be embedded. Then, through steps such as chemical mechanical polishing, a removal of a silicon nitride film, etc., as shown in FIG. 12, the separating insulation film STI is formed in the trench TC. Moreover, as shown in FIG. 13, an insulation film ZF is formed in the trench TC located in the region where the gate electrode of a transfer transistor is arranged. Next, the photo-resist pattern (not shown) which exposes the insulation film ZF is formed by using a predetermined photomechanical process.

Next, using the photo-resist pattern as an etching mask, by applying an etching treatment to the insulation film ZF, a portion of the insulation film ZF ranging from the surface thereof to a position of depth shallower than a bottom of the trench TC is removed. Then, the photo-resist pattern is removed. Accordingly, as shown in FIG. 14, a fin-like structure FS is formed by a portion of the semiconductor substrate SUB located between the trenches TC. In the fin-like structure FS, a depth from the surface of the semiconductor substrate SUB to a surface of a remaining insulation film ZF is defined as a height and a spacing between the trenches TC is defined as a width. Having the height and the width, the fin-like structure FS extends in the direction intersecting the direction in which the gate electrode extends.

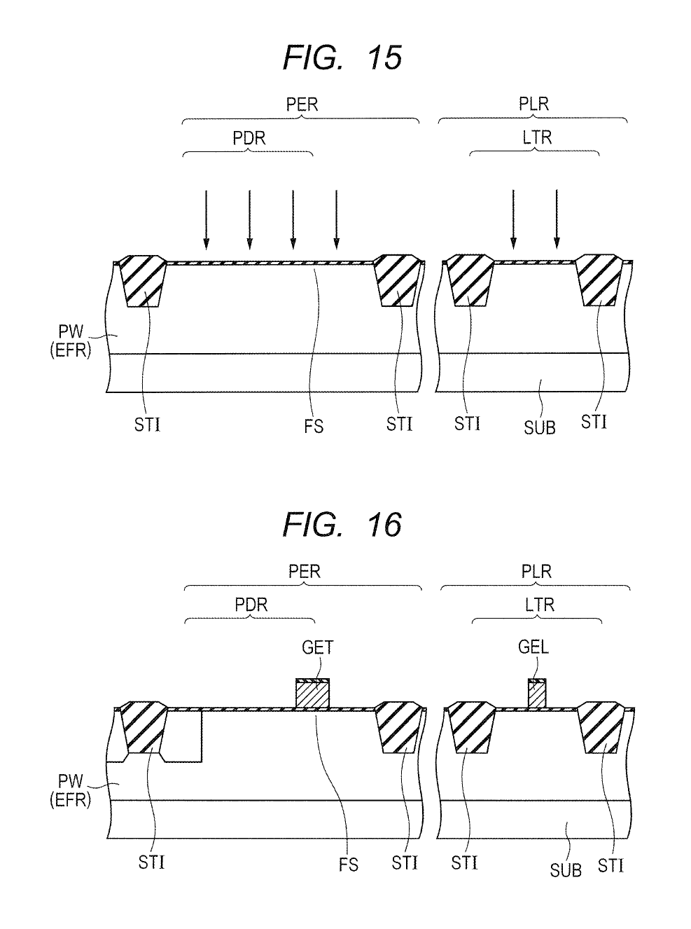

Next, as shown in FIG. 15, a P type well PW is formed in the pixel region PER etc. by introducing P type impurities, such as boron. Then, the silicon oxide film located over the surface of the P type well PW etc. is removed. Next, a silicon oxide film (not shown) to be a gate oxide film is newly formed over the surface of the P type well PW etc. by performing a thermal oxidation treatment. A poly-silicon film (not shown) is so formed as to cover the silicon oxide film.

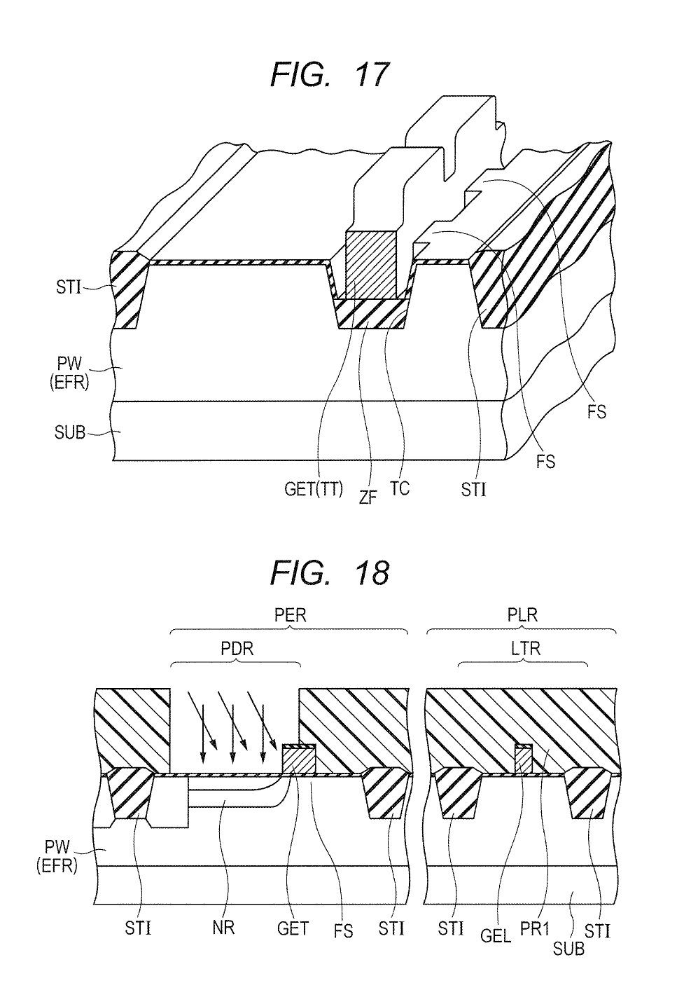

Next, by using a predetermined photomechanical process and etching, as shown in FIG. 16, the gate electrode GET of the transfer transistor is formed in the pixel region PER. The gate electrode GEL of the logic transistor is formed in the peripheral circuit region PLR. At this time, in the pixel region PER, as shown in FIG. 17, the gate electrode GET is so formed as to cover side surfaces and an upper surface of the fin-like structure FS.

Next, as shown in FIG. 18, by using the predetermined photomechanical process, a photo-resist pattern PR1 is formed. Then, by introducing N type impurities using the photo-resist pattern PR1 as an injection mask, an N type impurity region NR is formed in the photodiode formation region PDR. Subsequently, the photo-resist pattern PR1 is removed.

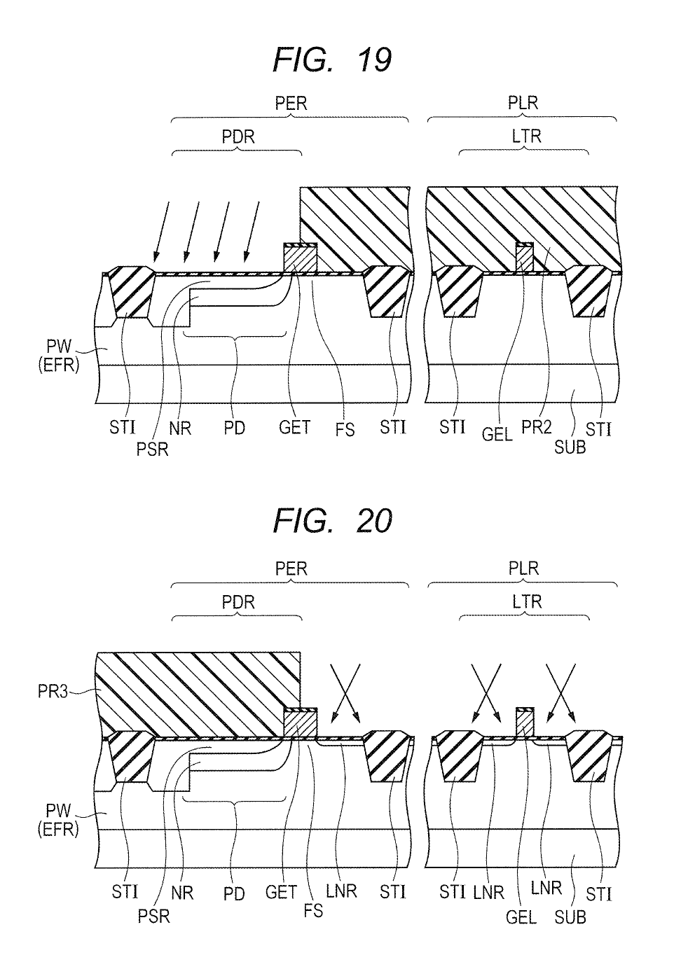

Next, as shown in FIG. 19, by using the predetermined photomechanical process, a photo-resist pattern PR2 is formed. Then, by introducing P type impurities using the photo-resist pattern PR2 as an injection mask, a P type impurity region PSR is formed in the photodiode formation region PDR. Thus, a PNP type photodiode PD comprised of the P type well PW, the N type impurity region, and the P type impurity region PSR is formed. Subsequently, the photo-resist pattern PR2 is removed.

Next, as shown in FIG. 20, by using the predetermined photomechanical process, a photo-resist pattern PR3 is formed. Then, by introducing N type impurities using the photo-resist pattern PR3 as an injection mask, an N type impurity region LNR is formed in a region where the floating diffusion region is formed. Also, the N type impurity region LNR is formed in the logic transistor formation region LTR. Subsequently, the photo-resist pattern PR3 is removed.

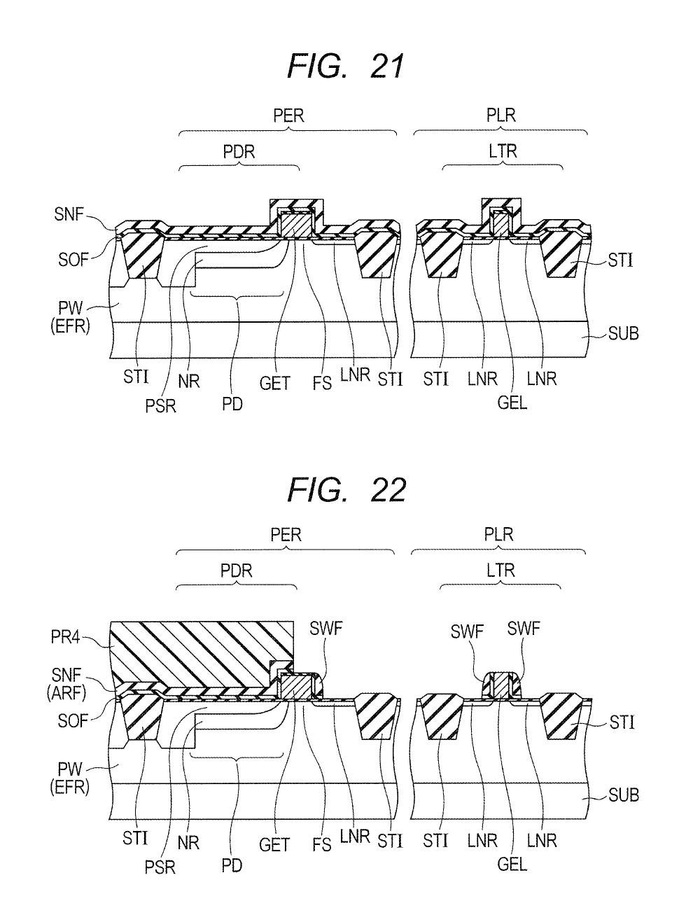

Next, as shown in FIG. 21, a silicon oxide film SOF and a silicon nitride film SNF are so formed as to cover the gate electrode GET, the gate electrode GEL, etc. Then, as shown in FIG. 22, by performing the predetermined photomechanical process, a photo-resist pattern PR4 is formed. Next, using the photo-resist pattern PR4 as an etching mask, by applying an anisotropic etching treatment to the exposed silicon nitride film SNF, there are formed sidewall insulation films SWF over both side surfaces of the gate electrode GEL as well as over one side surface of the gate electrode GET. Subsequently, the photo-resist pattern PR4 is removed.

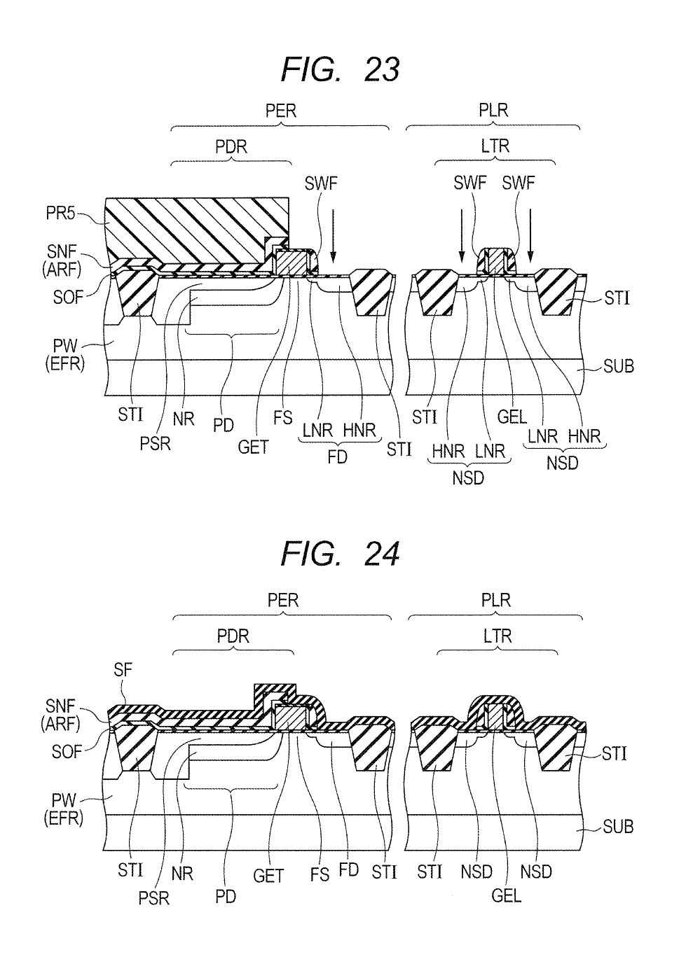

Next, as shown in FIG. 23, by using the predetermined photomechanical process, a photo-resist pattern PR5 is formed. Then, by introducing N type impurities using the photo-resist pattern PR5, the sidewall insulation film SWF, etc. as an injection mask, an N type impurity region HNR is formed in a region where the floating diffusion region is formed. Also, the N type impurity region HNR is formed in the logic transistor formation region LTR.

In the pixel region PER, the floating diffusion region FD is formed by the N type impurity regions LNR, and HNR. In the logic transistor formation region LTR, the N type source/drain region NSD is formed by the N type impurity regions LNR and HNR. Subsequently, the photo-resist pattern PR5 is removed.

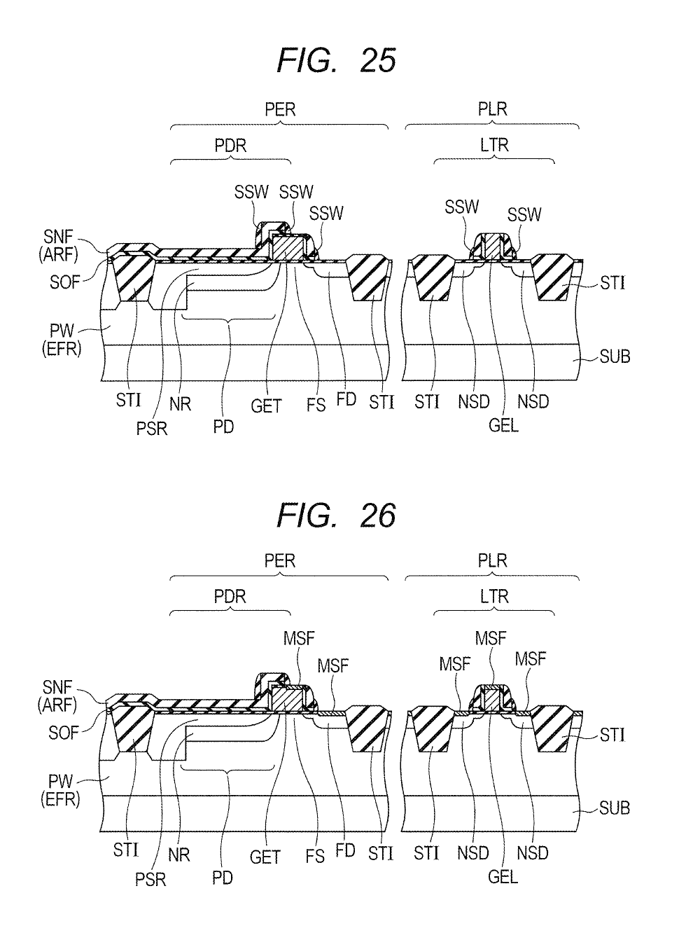

Next, as shown in FIG. 24, a silicon oxide film SF is so formed as to cover the remaining silicon nitride film SNF etc. Next, by applying an anisotropic etching treatment over the entire silicon oxide film SF, as shown in FIG. 25, a sidewall oxide film SSW is formed. Next, as shown in FIG. 26, a metal silicide film NSF is formed over the upper surface of the gate electrodes GET and GET, the surface of the floating diffusion region FD, and the surface of the source/drain region NSD by a SALICIDE (Self ALIgned siliCIDE) method.

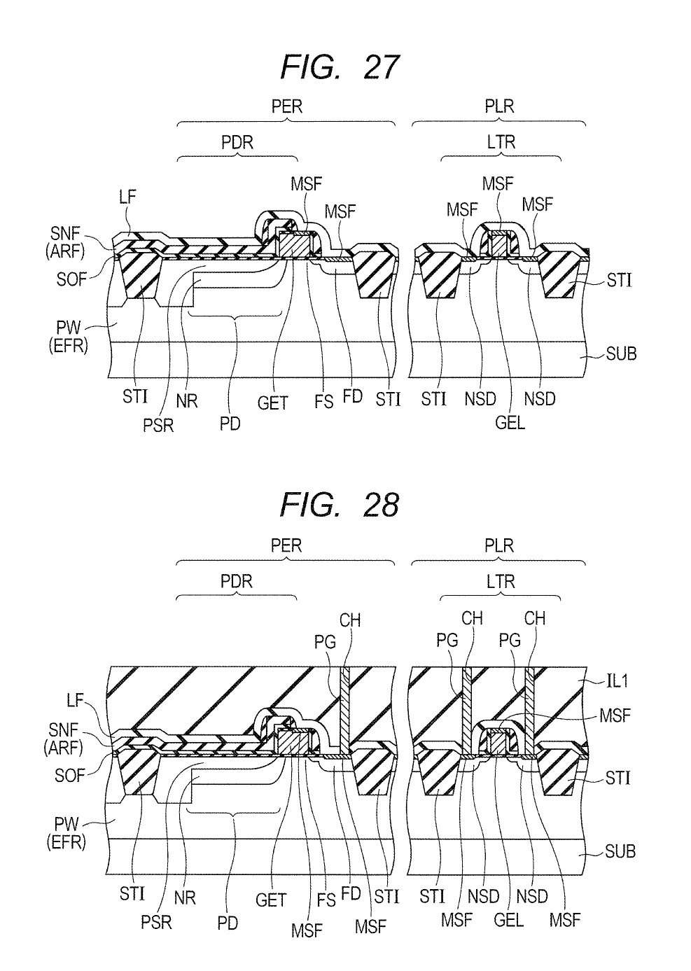

Next, as shown in FIG. 27, the liner film LF containing a silicon nitride film is so formed as to cover the gate electrodes GET and GEL etc. Next, a first interlayer insulation film IL1 containing a TEAS (Tetra Ethyl Ortho Silicate) film etc. is so formed as to cover the liner film LF. Next, by using the predetermined photomechanical process and etching, a contact hole CH which passes through the first interlayer insulation film IL1 etc. is formed. Next, as shown in FIG. 28, a contact plug PG which contains barrier metal and tungsten is formed in the contact hole CH.

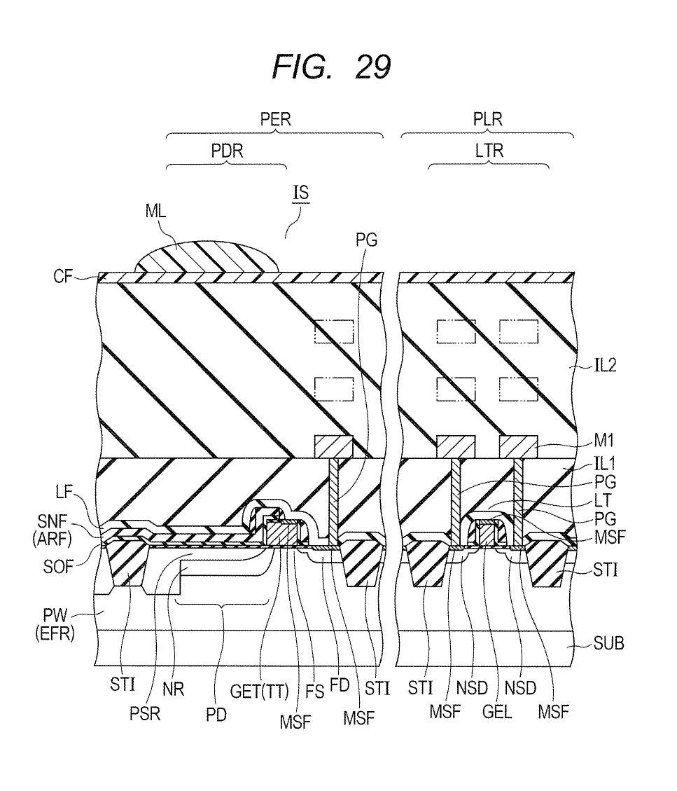

Next, as shown in FIG. 29, a plurality of wirings (two-dot chain line) including a first wiring M1 are formed in a second interlayer insulation film IL2 by repeating a general deposition process, an etching treatment, etc. Aluminum or copper is used as a wiring material for the first wiring M1 etc. When using copper as the material, the wiring may be formed by a damascene method. Then, by forming a color filter CF and a micro-lens ML, a principal part of the image pickup device IS is completed.

In the image pickup device described above, since the transfer transistor TT is of a fin type, charges generated at the photodiode PD can be transmitted reliably to the floating diffusion region FD. This will be explained in comparison with an image pickup device of a comparative example.

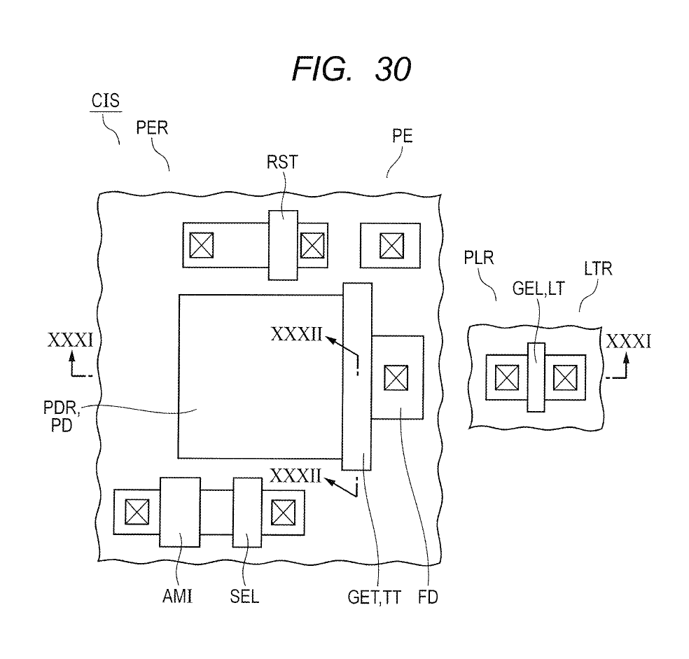

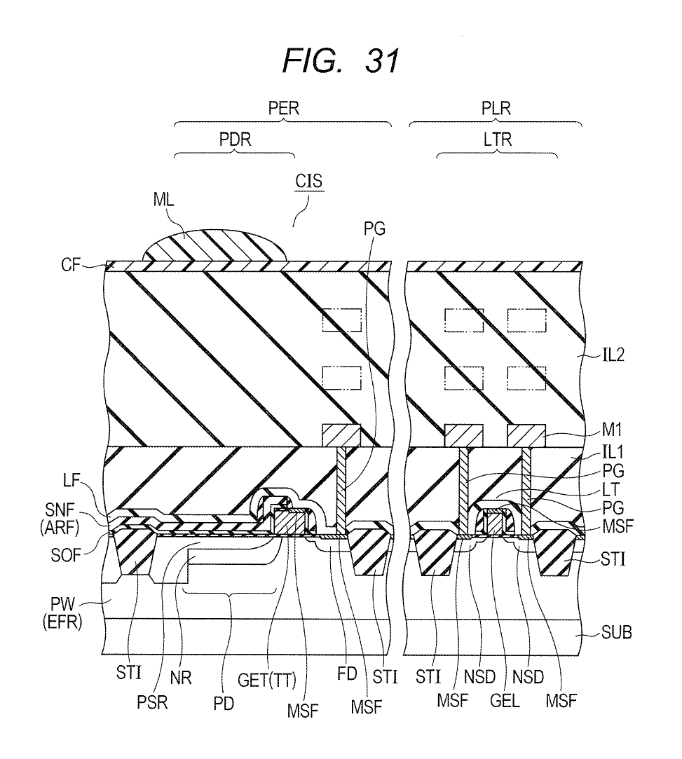

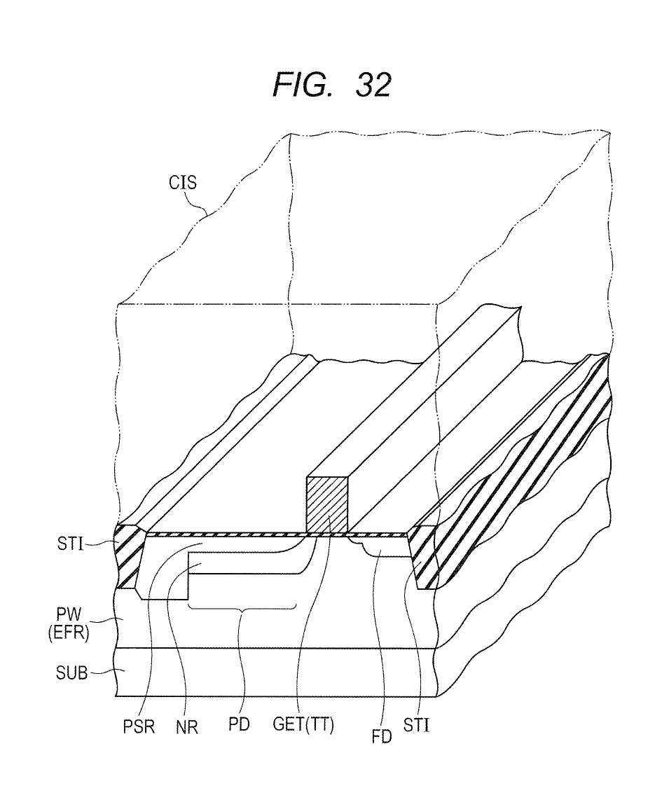

As shown in FIGS. 30 to 32, in the image pickup device CIS according to the comparative example, the transfer transistor TT is of a planar type. The gate electrode GET of the transfer transistor TT is formed across a flat P type well PW. Except for this configuration, the image pickup device CIS according to the comparative example is similar to the image pickup device IS shown in FIGS. 4 to 6. Therefore, the same or similar parts are denoted by the same reference characters and description thereof is not repeated unless necessary.

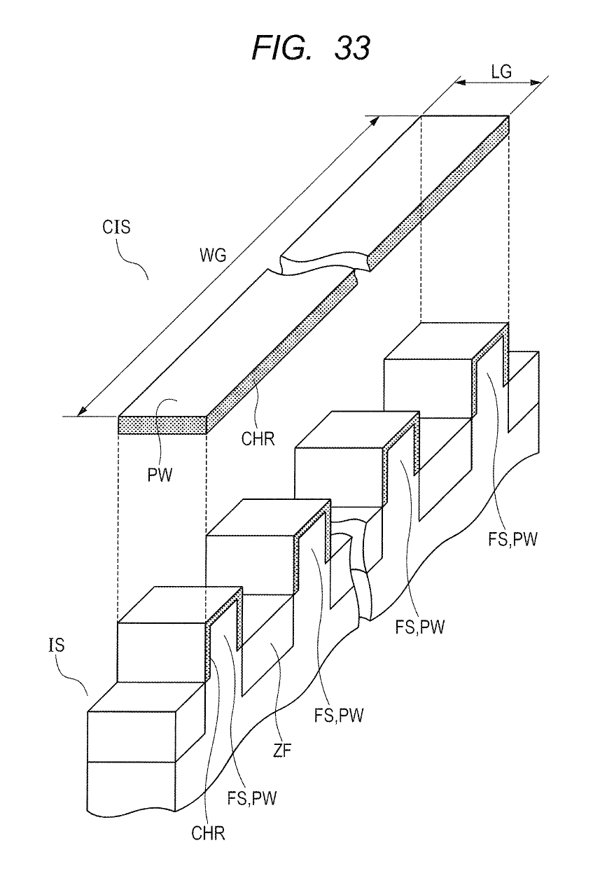

Now, in FIG. 33, a channel region formed in a portion of a P type well by the transfer transistor is shown schematically. In the image pickup device CIS according to the comparative example, a channel region CHR (gate length LG, gate width WG) is formed in a region of a flat P type well PW.

On the other hand, in the image pickup device IS according to the present embodiment, a channel region CHR is formed over side surfaces and upper surfaces of the fin-like structures FS (P type well PW). The fin-like structures FS are formed such that a whole area of the channel region CHR combining an area of the side surfaces and an area of the upper surfaces of the fin-like structures FS is larger than an area of the planar type channel region CHR. Accordingly, even if the gate length LG of the image pickup device IS and that of the comparative example are the same, an effective length of a gate width of the image pickup device IS becomes longer than the gate width of the comparative example. As a result, charges generated at the photodiode PD can be transmitted completely to the floating diffusion region FD.

### Modification

With regard to the image pickup device described above, there has been given the explanation of the front-side illumination type (FSI) image pickup device where light is allowed to enter from a front side (the side where the photodiode is formed) of the semiconductor substrate. Now, as a modification, there will be given an explanation of a back-side illumination type (BSI) image pickup device where light is allowed to enter from a back side of the semiconductor substrate.

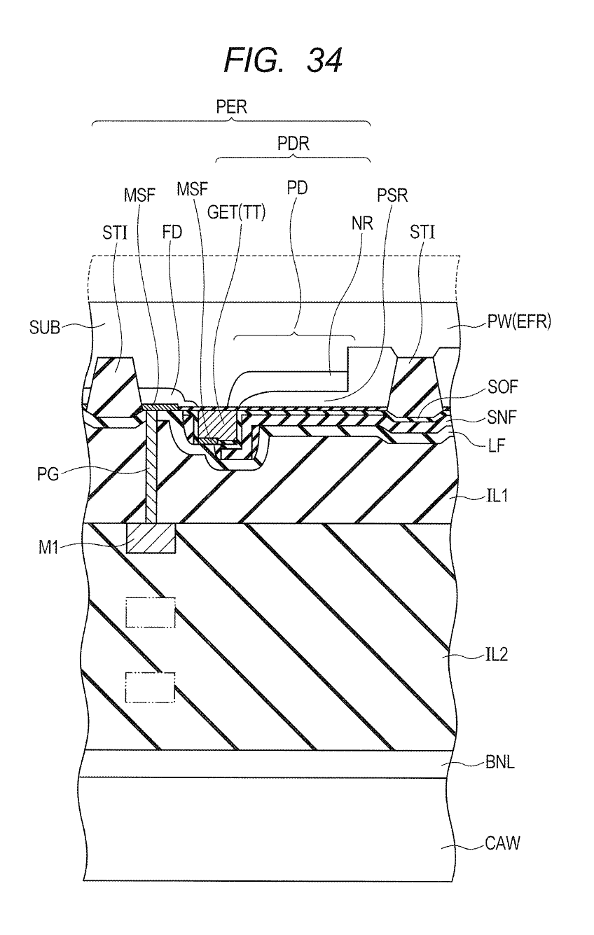

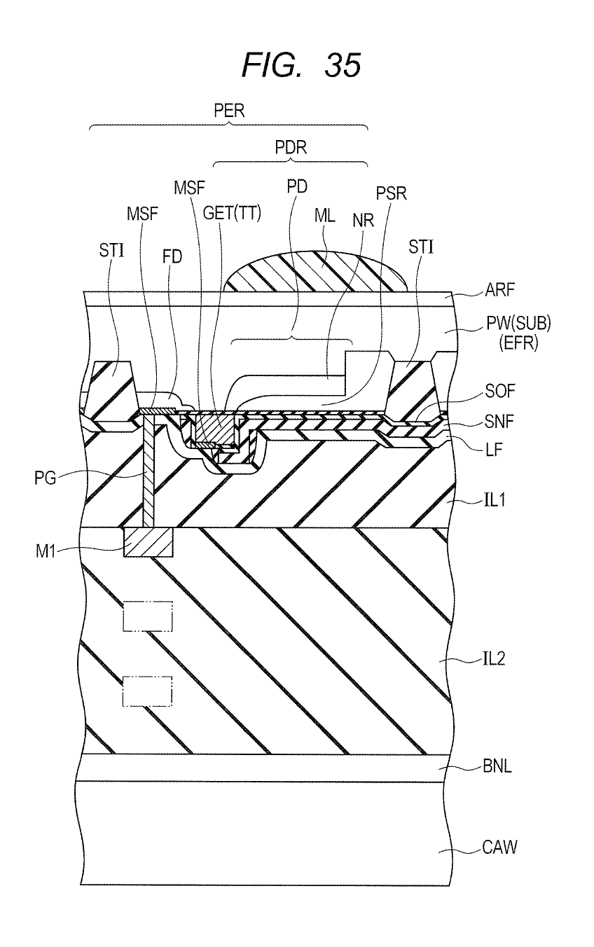

First, after the second interlayer insulation film IL2 shown in FIG. 34 has been formed, a carrier wafer CAW is joined to the second interlayer insulation layer via a joining layer BNL. Next, by grinding a back side of a semiconductor substrate SUB, the semiconductor substrate SUB is thinned to a desired thickness. Then, as shown in FIG. 35, a micro-lens ML is formed over the back surface of the semiconductor substrate SUB via an antireflection coating film ARF etc. Thus, a principal part of the back-side illumination type image pickup device is completed.

In the back-side illumination type image pickup device, incident light from the back side of the semiconductor substrate SUB thinned by grinding is led to the photodiode PD formed on a front side of the semiconductor substrate SUB. As a result, the attenuation of the light reaching the photodiode PD is suppressed, which contributes to improvement in the sensitivity of the image pickup device.

### Second Embodiment

Now, there will be given an explanation of one example of an image pickup device in which heights of the fin-like structures of the transfer transistor differ from one another according to pixel regions for red light, green light, and blue light.

In the pixel region PER (see FIG. 2) of the image pickup device, pixel parts PE according to wavelengths of light are arranged. That is, over the semiconductor substrate, there are arranged a red pixel region where charges are generated by mainly receiving red light (a first wavelength), a green pixel region where charges are generated by mainly receiving green light (a second wavelength), and a blue pixel region where charges are generated by mainly receiving blue light (a third wavelength) at predetermined positions, respectively.

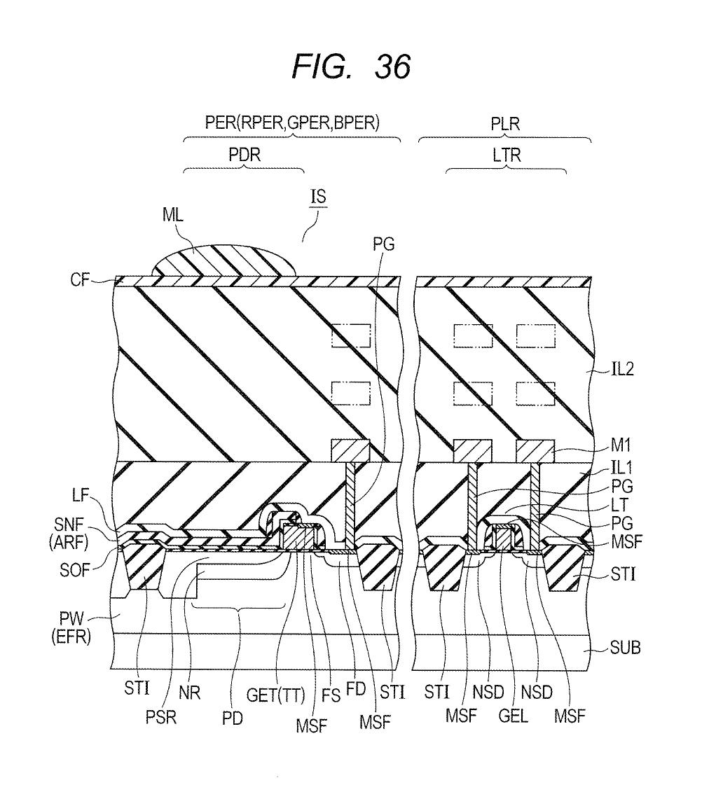

FIG. 36 shows, in a sectional view, the red pixel region RPER, the green pixel region GPER, and the blue pixel region BPER typically as one pixel region PER. Except for the heights of the fin-like structures of the transfer transistor TT being different according to corresponding colors, the image pickup device of Second Embodiment is similar to the image pickup device shown in FIG. 5 etc. Therefore, the same or similar parts are denoted by the same reference characters and description thereof is not repeated unless necessary.

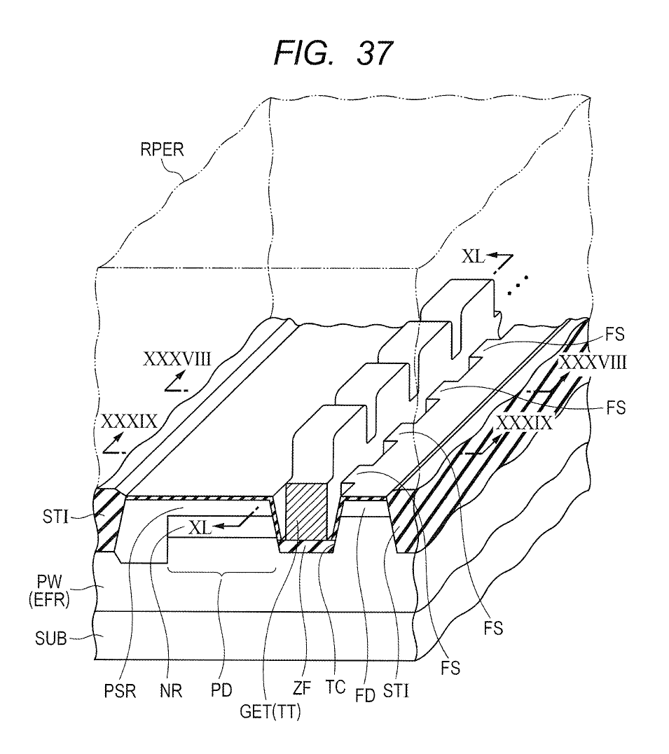

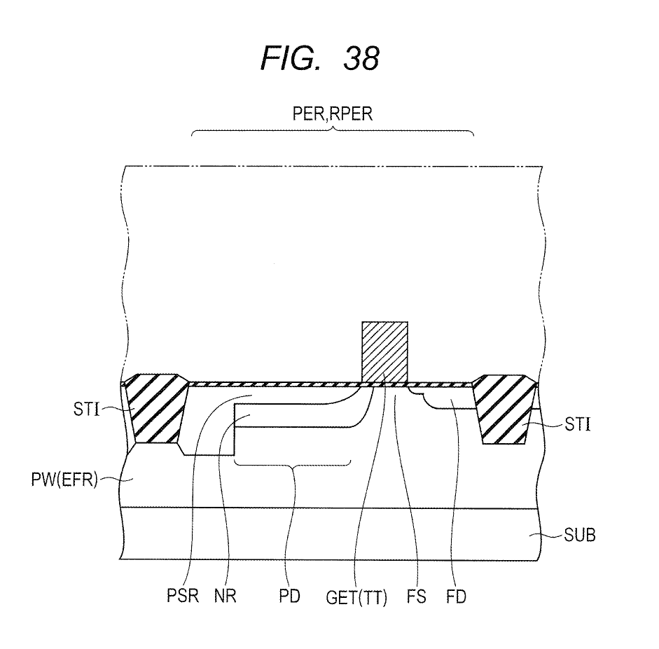

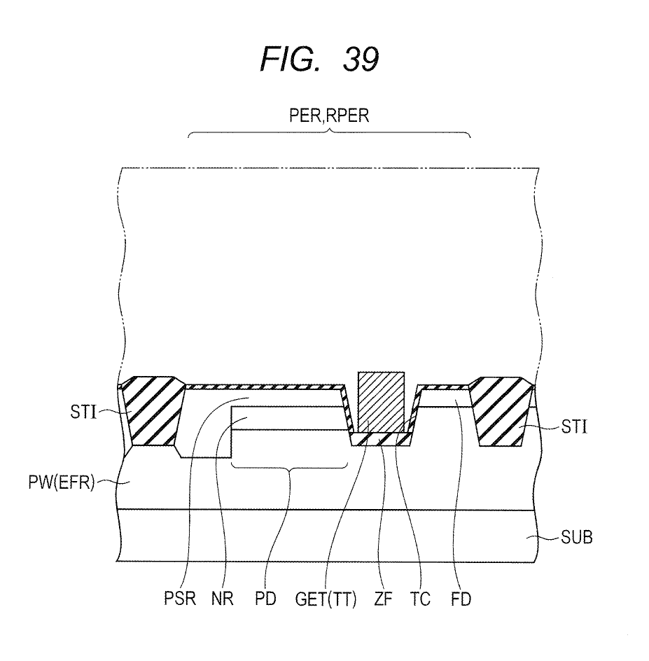

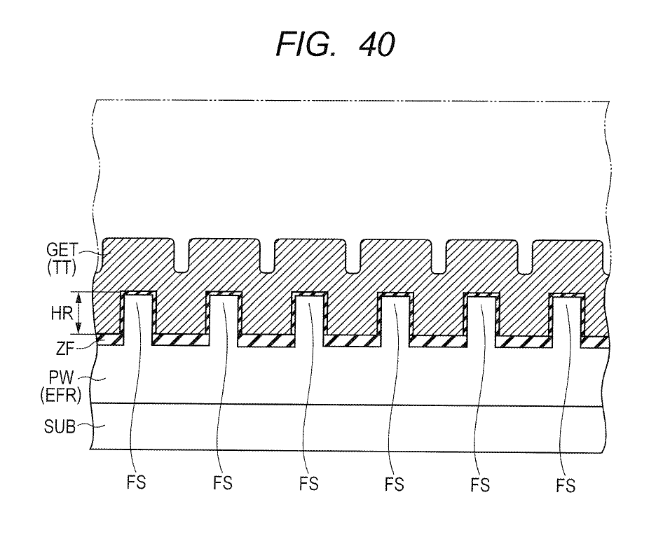

Next, the configuration of the transfer transistor and its periphery will be described. First, a transfer transistor TT formed in the red pixel region RPER will be shown in FIGS. 37 to 40. in the fin-like structure FS, a depth from a surface of the P type well PW (semiconductor substrate SUB) to an insulation film ZF is defined as a height HR. The height HR is set to the highest value in the fin-like structure formed in each of the red pixel region RPER, the green pixel region GPER, and the blue pixel region BPER.

Having the height HR and a width, the fin-like structure FS extends in a direction intersecting the direction in which the gate electrode GET extends. The gate electrode GET is so formed as to cover opposing side surfaces and an upper surface of each fin-like structure FS. By applying a voltage of a threshold value or grater to the gate electrode GET, a channel region is formed in each fin-like structure FS.

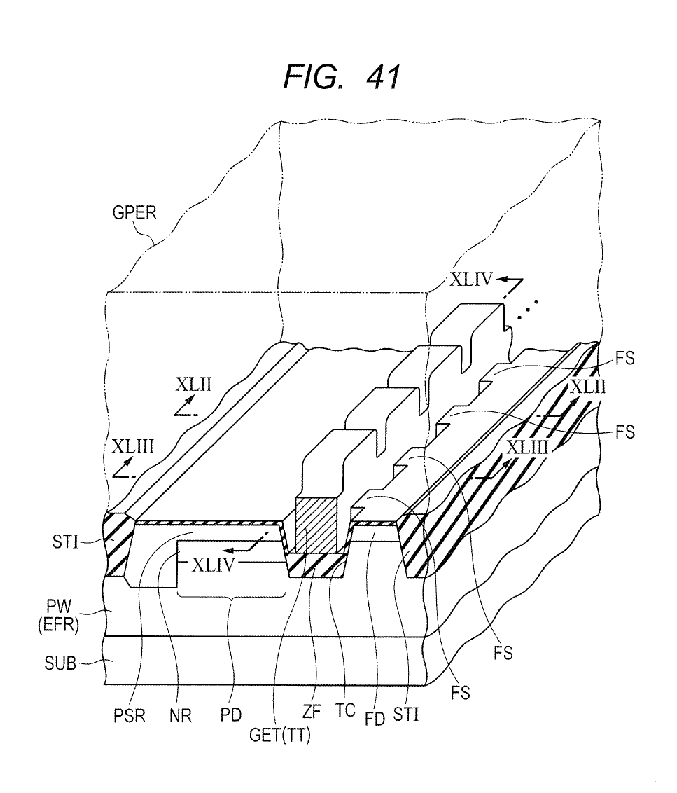

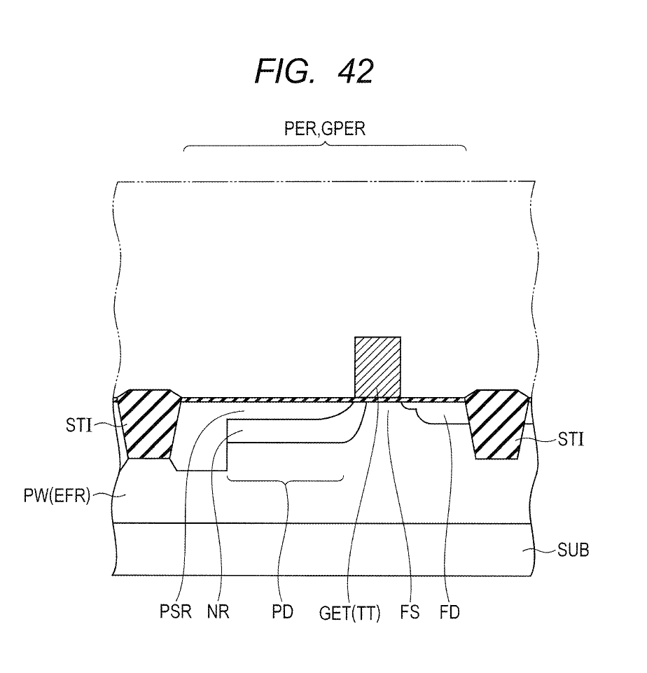

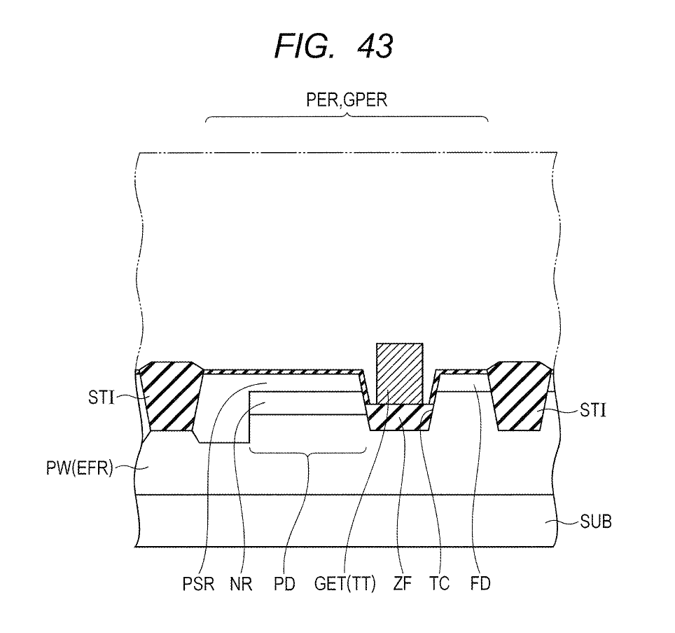

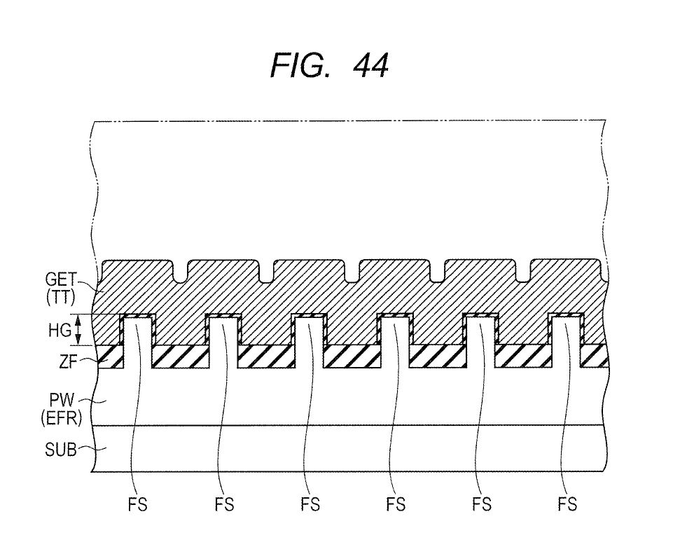

Next, a transfer transistor TT formed in the green pixel region GPER will be shown in FIGS. 41 to 44. In the fin-like structure FS, a depth from the surface of the P type well PW (semiconductor substrate SUB) to the insulation film ZF is defined as a height HG. Among heights of the fin-like structures formed in the red pixel region RPER, the green pixel region GPER, and the blue pixel region BPER, respectively, the height HG is set to the second highest value.

Having the height HG and a width, the fin-like structure FS extends in the direction intersecting the direction in which the gate electrode GET extends. The gate electrode GET is so formed as to cover opposing side surfaces and an upper surface of each fin-like structure FS. By applying the voltage of the threshold value or greater to the gate electrode GET, a channel region is formed in each fin-like structure FS.

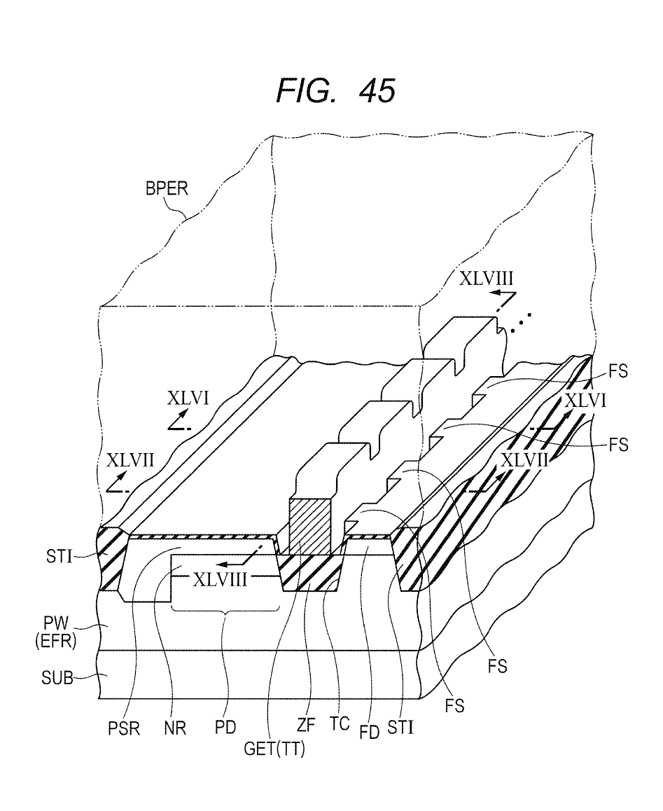

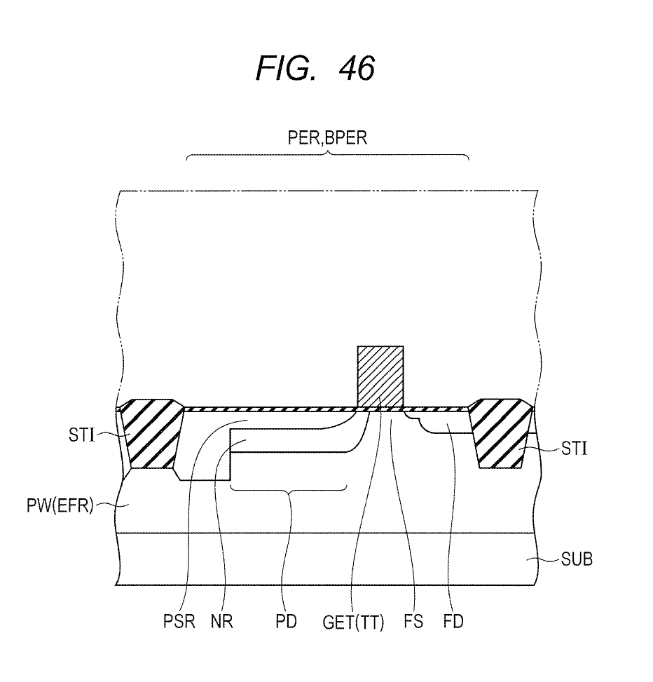

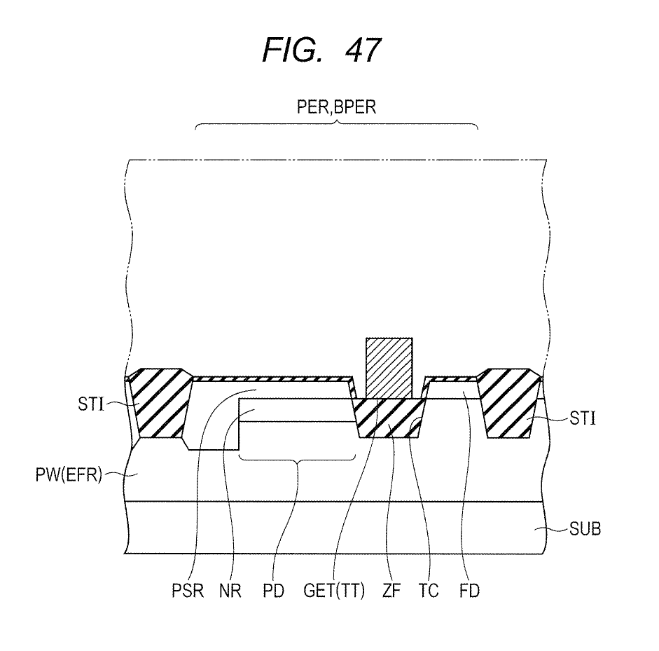

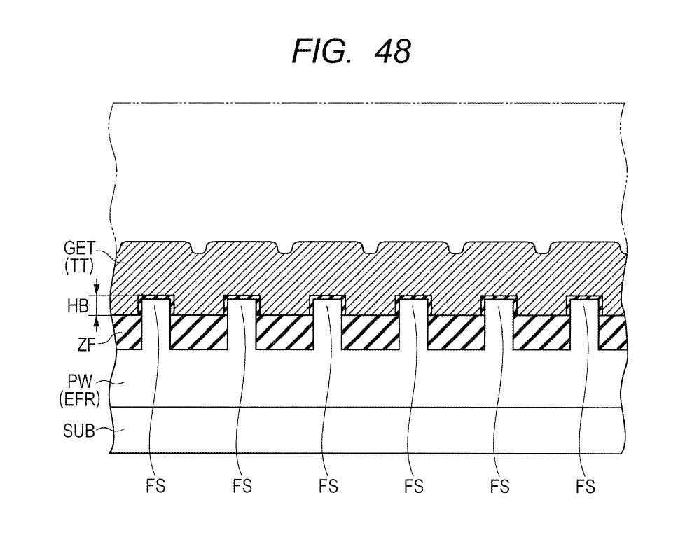

Next, a transfer transistor TT formed in the blue pixel region BPER will be shown in FIGS. 45 to 48. In the fin-like structure FS, a depth from the surface of the P type well PW (semiconductor substrate SUB) to the insulation film ZF is defined as a height HB. Among heights of the fin-like structures FS formed in the red pixel region RPER, the green pixel region GPER, and the blue pixel region BPER, respectively, the height HB is set to the lowest value.

Having the height HB and a width, the fin-like structure FS extends in the direction intersecting the direction in which the gate electrode GET extends. The gate electrode GET is so formed as to cover the opposing side surfaces and the upper surface of each fin-like structure FS. By applying the voltage of the threshold value or greater to the gate electrode GET, a channel region is formed in each fin-like structure FS. The principal part of the image pickup device according to Second Embodiment is configured as described above.

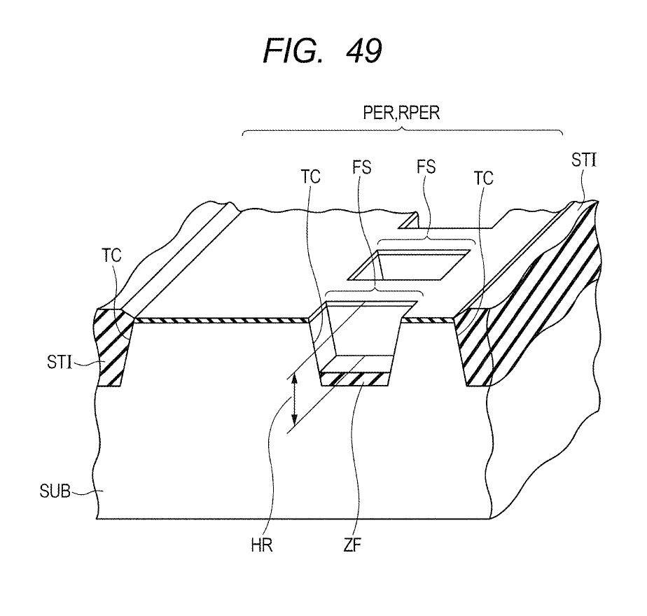

Next, one example of a method for manufacturing the image pickup device described above will be explained. First, after going through steps similar to those shown in FIGS. 10 to 13, by using a predetermined photomechanical process, there is formed a photo-resist pattern exposing an insulation film ZF formed in a trench TC located in the red pixel region RPER (see FIG. 49) and covering other regions. Then, by performing an etching treatment using the photo-resist pattern as an etching mask, a portion of the insulation film ZF ranging from the surface of the semiconductor substrate SUB to a depth corresponding to the height HR is removed. Subsequently, the photo-resist pattern is removed. Thus, as shown in FIG. 49, a fin-like structure FS corresponding to the height HR is formed in the red pixel region RPER.

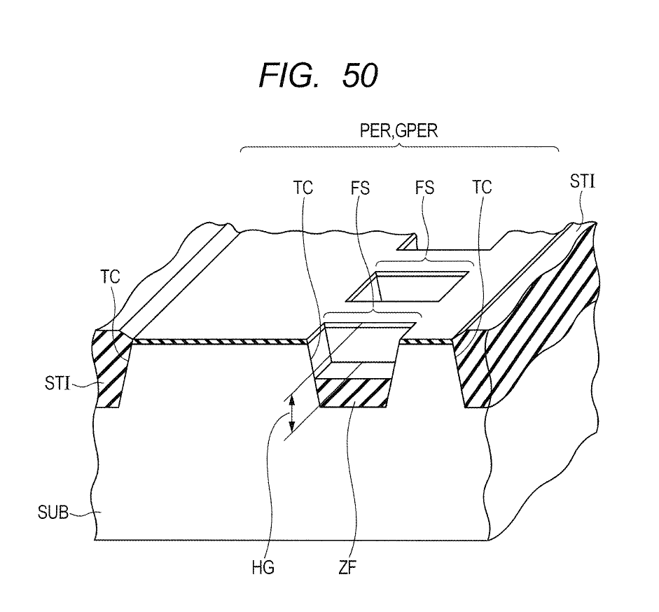

Next, by using the predetermined photomechanical process, there is formed a photo-resist pattern exposing an insulation film ZF formed in a trench TC located in the green pixel region GPER (see FIG. 50) and covering other regions. Then, by performing an etching treatment using the photo-resist pattern as an etching mask, a portion of the insulation film ZF ranging from the surface of the semiconductor substrate SUB to a depth corresponding to the height HG is removed. Subsequently, the photo-resist pattern removed. Thus, as shown in FIG. 50, a fin-like structure FS corresponding to the height HG is formed in the green pixel region GPER.

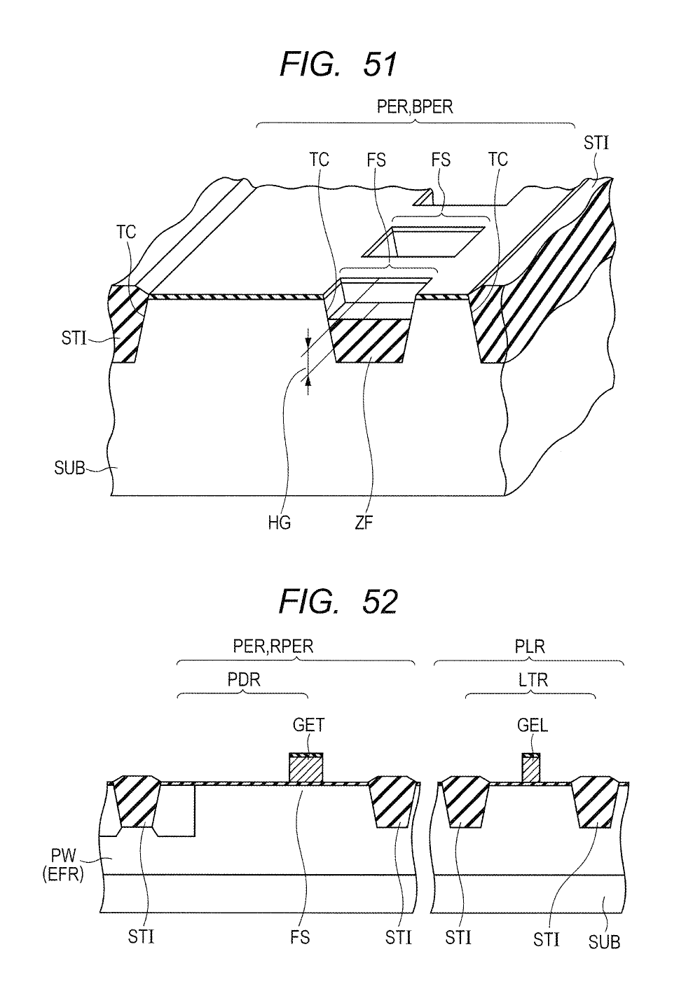

Next, by using the predetermined photomechanical process, there is formed a photo-resist pattern exposing an insulation film ZF formed in a trench TC located in the blue pixel region BPER (see FIG. 51) and covering other regions. Then, by performing an etching treatment using the photo-resist pattern as an etching mask, a portion of the insulation film ZF ranging from the surface of the semiconductor substrate SUB to a depth corresponding to the height HB is removed. Subsequently, the photo-resist pattern is removed. Thus, as shown in FIG. 51, a fin-like structure FS corresponding to the height HB is formed in the blue pixel region BPER.

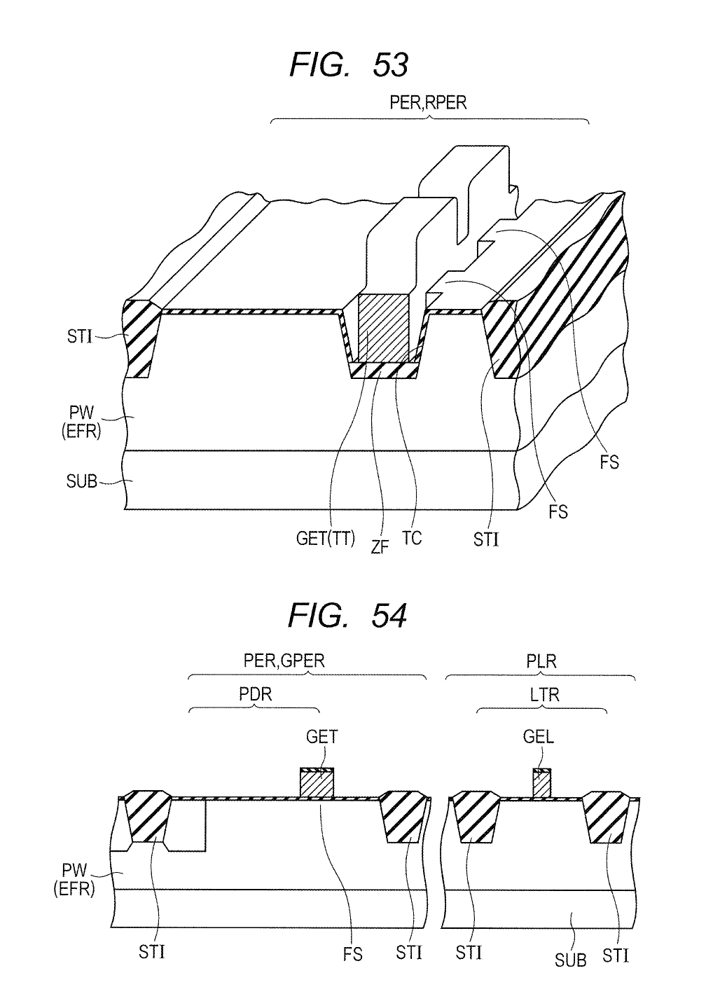

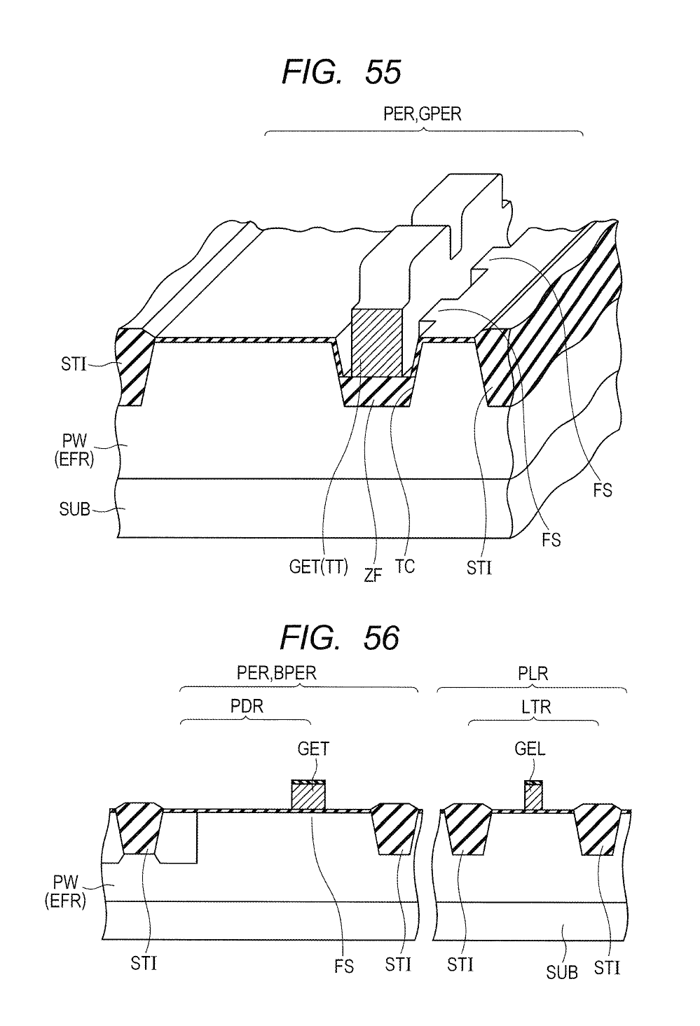

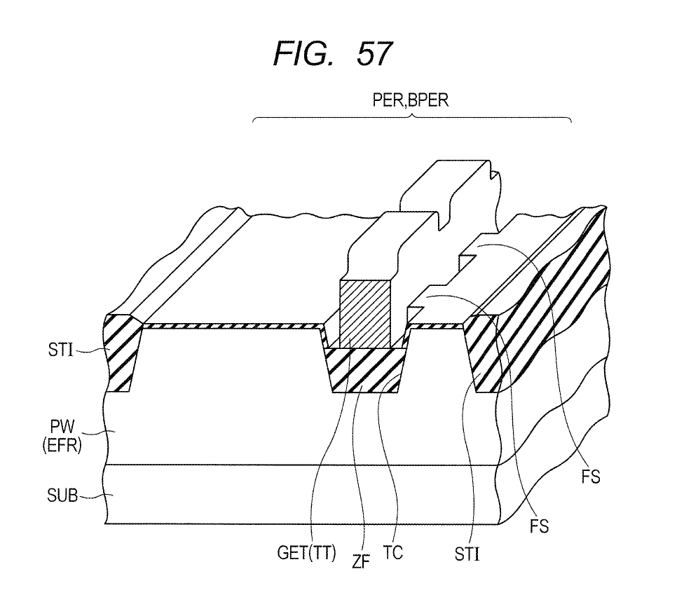

Next, after going through steps similar to those shown in FIGS. 15 and 16, the gate electrode of each transistor is formed. At this time, as shown in FIGS. 52 and 53, in the red pixel region RPER, the gate electrode GET of the transfer transistor TT is so formed as to cover the side surfaces and the upper surface of the fin-like structure FS of the height HR (see FIG. 49). As shown in FIGS. 54 and 55, in the green pixel region GPER, the gate electrode GET of the transfer transistor TT is so formed as to cover the side surfaces and the upper surface of the fin-like structure FS of the height HG (see FIG. 50). As shown in FIGS. 56 and 57, in the blue pixel region BPER, the gate electrode GET of the transfer transistor TT is so formed as to cover the side surfaces and the upper surface of the fin-like structure FS of the height HB (see FIG. 51).

Through steps similar to those shown in FIGS. 18 to 29, the principal part of the image pickup device shown in FIG. 36 etc. is completed. Also, through steps similar to those shown in FIGS. 34 and 35, the image pickup device concerned maybe allowed to be a back-side illumination type image pickup device.

In the image pickup device, as to light entering a photodiode formation region PDR (photodiode PD), a position (depth) where charges are mainly generated depends upon a wavelength of the light. That is, the longer the wavelength of the light is, the deeper position the charges are generated at.

In the image pickup device described above, the height (height HR) of the fin-like structure FS formed in the red pixel region RPER is the highest and the height (height HB) of the fin-like structure FS formed in the blue pixel region BPER, is the lowest. The height (height HG) of the fin-like structure FS formed in the green pixel region GPER is higher than the height HB but lower than the height HR.

That is, the fin-like structure FS formed in the red pixel region RPER is formed as a portion from a surface of the P type well PW (semiconductor substrate SUB) to a deepest position (position A). The fin-like structure FS formed in the green pixel region GPER is formed as a portion from the surface of the P type well PW (semiconductor substrate SUB) to a position (position B) shallower than the position A. The fin-like structure FS formed in the blue pixel region BPER is formed as a portion from the surface of the P type well PW (semiconductor substrate SUB) to a position shallower than the position B.

Consequently, in the red pixel region RPER, charges mainly generated at a relatively deep position (depth A) can be transmitted efficiently through a channel region to be formed in the fin-like structure FS being formed from the surface of the P type well PW to the deepest position.

Further, in the green pixel region GPER, charges mainly generated at a position (depth B) shallower than the depth A can be transmitted efficiently through a channel region to be formed in the fin-like structure FS being formed from the surface of the P type well PW to a second deepest position.

Still further, in the blue pixel region BPER, charges mainly generated at a relatively shallow position, which is shallower than depth B, can be transmitted efficiently through a channel region to be formed in the fin-like structure FS being formed from the surface of the P type well PW to a shallowest position.

### Modification

In each of the red pixel region RPER, the green pixel region GPER, and the blue pixel region BPER, according to the height of the fin-like structure FS, the position (depth) of the N type impurity region NR for forming the photodiode PD may be changed.

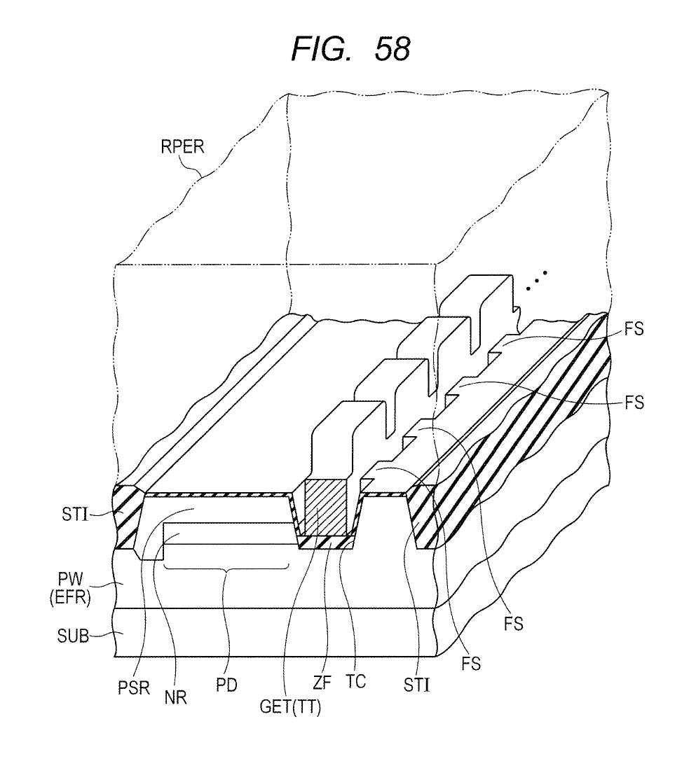

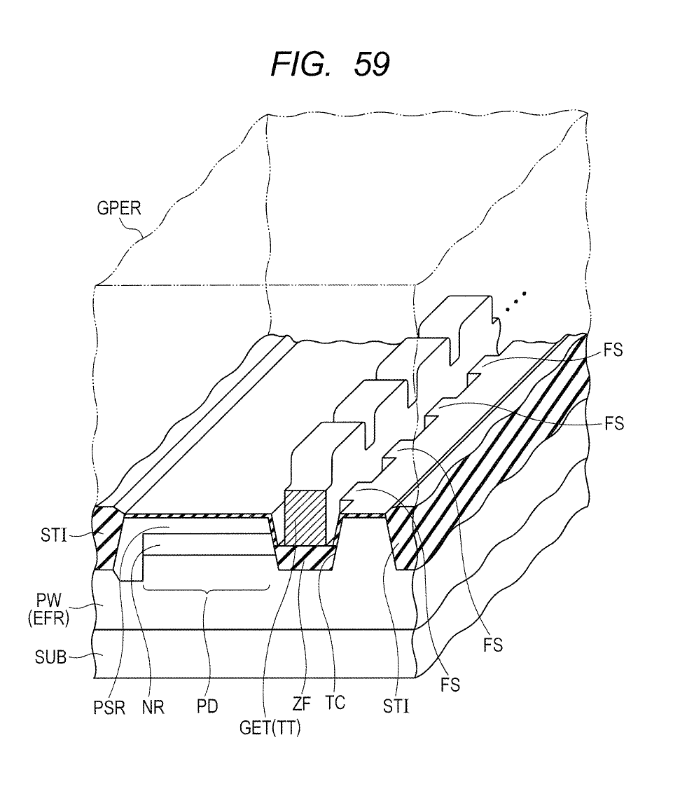

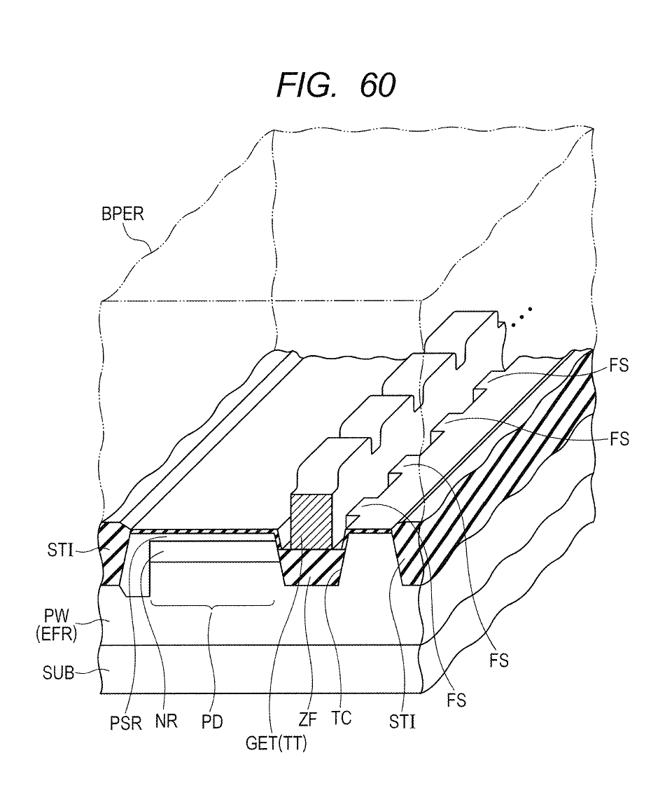

As shown in FIG. 58, the N type impurity region NR is formed at the deepest position in the red pixel region RPER. Further, as shown in FIG. 59, the N type impurity region NR is formed at the second deepest position in the green pixel region GPER. Still further, as shown in FIG. 60, the N type impurity region NR is formed at the shallowest position in the blue pixel region BPER. The generated charges can be transmitted more efficiently by setting the depth position of the N type impurity region according to the location where the charges are generated.

### Third Embodiment

Now, one example of variations of the logic transistor will be explained.

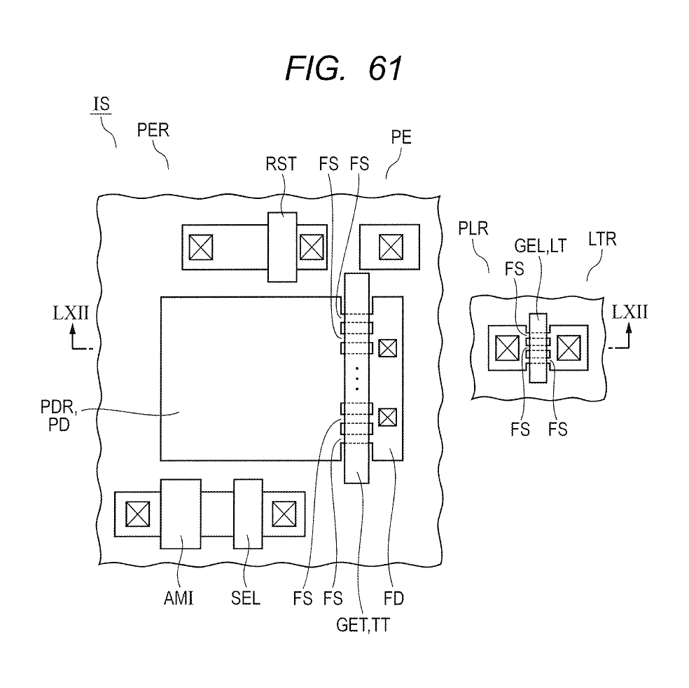

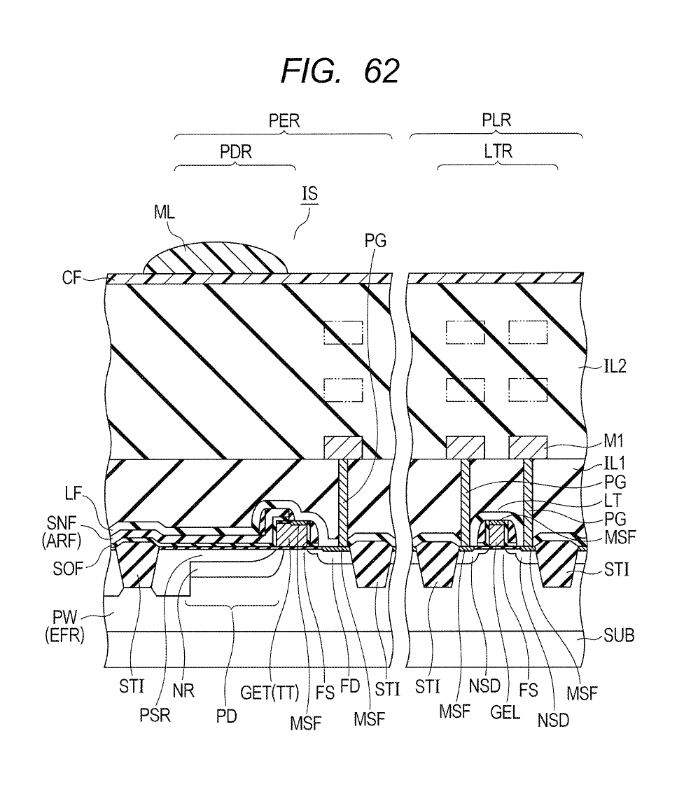

In the image pickup device according to each embodiment described above, there has been given the explanation of an example where the transfer transistor is of a fin type and the logic transistor as a peripheral transistor is of a planar type. In an image pickup device according to Third Embodiment, as shown in FIGS. 61 to 63, in addition to the fin type transfer transistor TT, the logic transistor LT is also of the fin type in which a fin-like structure FS is formed.

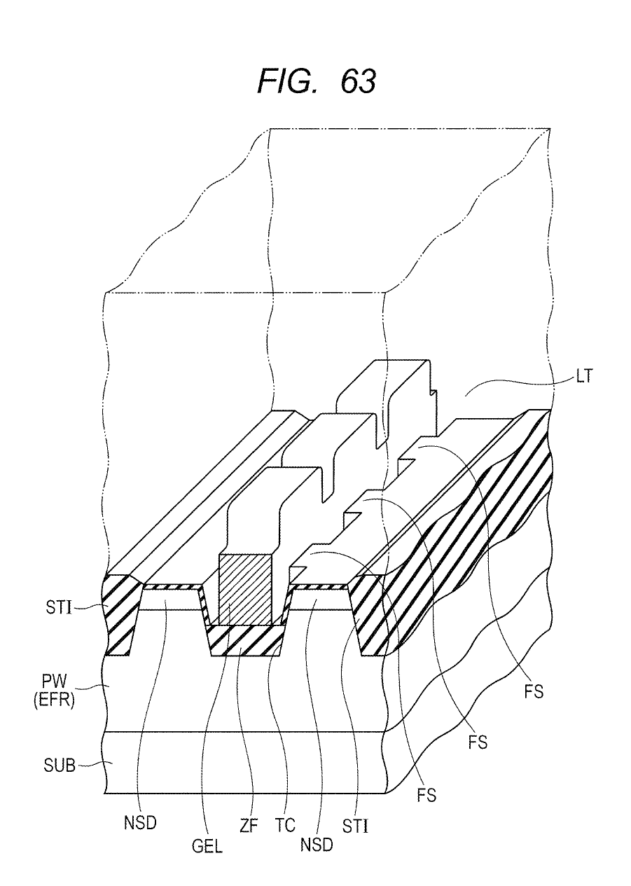

In particular, as shown in FIG. 63, the gate electrode GEL of the logic transistor LT is so formed as to cover the side surfaces and the upper surface of the fin-like structure FS. Except for this configuration, the image pickup device of Third Embodiment is similar to the image pickup device shown in FIGS. 4 to 6. Therefore, the same or similar parts are denoted by the same reference characters and description thereof is not repeated unless necessary.

Simply by changing a trench pattern, the image pickup device described above can be manufactured by a method similar to the one explained in First Embodiment. First, in the step shown in FIG. 10, as in the case of the transfer transistor, a trench is formed in a region where a gate electrode of the logic transistor is to be formed. Then, through steps similar to those shown in FIGS. 12 to 29, the image pickup device, whose transfer transistor TT and logic transistor LT are of fin types, respectively, is manufactured.

In the image pickup device described above, first, since the transfer transistor TT is of a fin type, charges generated at the photodiode PD can be transmitted to the floating diffusion region FD completely. Further, the logic transistor LT is of a fin type, and fin-like structures FS are formed such that a whole area of a channel region CHR combining an area of the side surfaces and an area of the upper surfaces of the fin-like structures FS is larger than an area of a planar type channel region CHR. Accordingly, an effective length of the gate width of the image pickup device described above becomes longer than a length of a gate width of the planar type logic transistor. Therefore, a greater amount of electric currents can be sent by the logic transistor LT.

Now, the case of the image pickup device where the height of the fin-like structure of the transfer transistor is changed according to red, green, or blue is considered. With regard to the height of the fin-like structure of the logic transistor, in terms of sending a large amount of electric currents, it is desirable to set it to the same level as the fin-like structure of the red pixel region, which is the highest.

### Modification

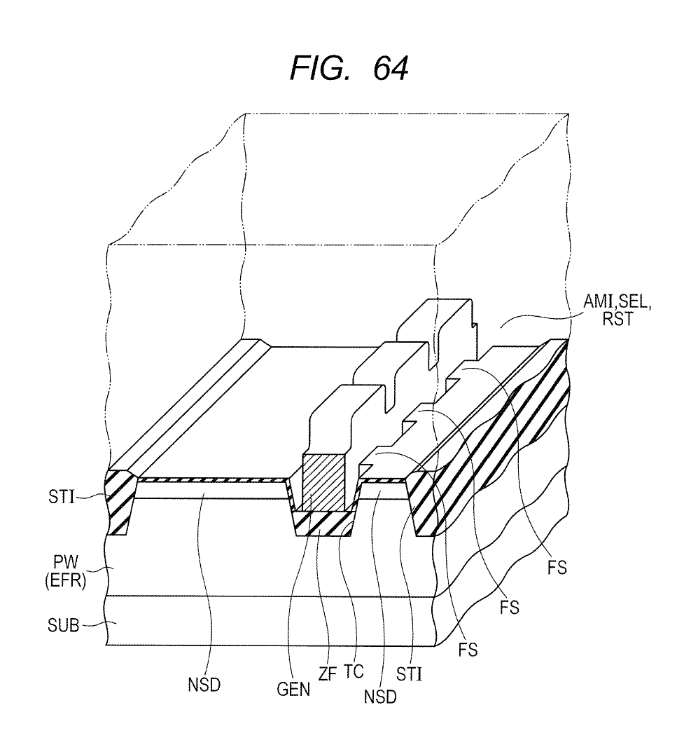

When the logic transistor LT is of a fin type, it is desirable to also use a fin type pixel transistor in the pixel region. As shown in FIG. 64, each of the amplifying transistor AMI, the selection transistor SEL, and the resetting transistor RST is of a fin type. As to the logic transistor, there is a logic transistor which operates on a relatively high voltage, and the pixel transistor also operates on a high voltage. In the image pickup device according to the present modification, a consistency of operation can be achieved by also using the pixel transistor of a fin type together with the logic transistor.

Further, the image pickup devices according to the above embodiments can be variously combined as required.

Although the invention made by the present inventors has been specifically described based on the preferred embodiments, the invention is not limited thereto. it is apparent that various modifications can be made to the embodiments without departing from the scope of the invention.

What is claimed is:

1. An image pickup device, comprising:
a semiconductor substrate;
element formation regions prescribed, respectively, by separating insulation films formed over the semiconductor substrate, including a pixel region and a peripheral circuit region;
a gate electrode formed in the element formation region, including a transfer gate electrode of a transfer transistor formed in the pixel region;
a photoelectric conversion part formed in a portion of the pixel region located on one side across the transfer gate electrode;
a floating diffusion region formed in a portion of the pixel region located on the other side across the transfer gate electrode; and
a fin-like structure formed in the element formation region and including a pixel fin-like structure which is formed in the pixel region, the structure extending, with a depth from a surface of the semiconductor substrate to a position of depth deeper than the surface being as a height, while having the height and width, in a direction intersecting a direction in which the transfer gate electrode extends, and joining the photoelectric conversion part with the floating diffusion region,
wherein the transfer gate electrode is so formed as to cover a surface of the pixel fin-like structure.

2. The image pickup device according to claim 1,
wherein the element formation region includes, as the pixel regions:
a first pixel region corresponding to light of a first wavelength;
a second pixel region corresponding to light of a second wavelength shorter than the first wavelength; and
a third pixel region corresponding to light of a third wavelength shorter than the second wavelength, respectively,
wherein the transfer gate electrode includes:
a first transfer gate electrode formed in the first pixel region;
a second transfer gate electrode formed in the second pixel region; and
a third transfer gate electrode formed in the third pixel region,
wherein the photoelectric conversion part includes:
a first photoelectric conversion part formed in the first pixel region;
a second photoelectric conversion part formed in the second pixel region; and
a third photoelectric conversion part formed in the third pixel region,
wherein the floating diffusion region includes:
a first floating diffusion region formed in the first pixel region;
a second floating diffusion region formed in the second pixel region; and
a third floating diffusion region formed in the third pixel region, and
wherein the pixel fin-like structure includes:
a first pixel fin-like structure which is formed in the first pixel region, which extends having a first height and the width, and which joins the first photoelectric conversion part with the first floating diffusion region;
a second pixel fin-like structure which is formed in the second pixel region, which extends having a second height and the width, and which joins the second photoelectric conversion part with the second floating diffusion region; and
a third pixel fin-like structure which is formed in the third pixel region, which extends having a third height and the width, and which joins the third photoelectric conversion part with the third floating diffusion region,
the first height, the second height, and the third height being different from one another.

3. The image pickup device according to claim 2,
wherein the photoelectric conversion part includes a second conductive type impurity region formed in a first conductive type region as the pixel region,
wherein the first photoelectric conversion part includes a first impurity region as the impurity region,
wherein the second photoelectric conversion part includes a second impurity region as the impurity region,
wherein the third photoelectric conversion part includes a third impurity region as the impurity region, and
wherein the first impurity region, the second impurity region, and the third impurity region are formed at different positions of depth based on the first height, the second height, and the third height, respectively.

4. The image pickup device according to claim 1,
wherein the gate electrode includes a peripheral gate electrode of a peripheral transistor formed in the peripheral circuit region, and
wherein the peripheral gate electrode is so formed as to cover a planar surface of the peripheral circuit region.

5. The image pickup device according to claim 1,
wherein the gate electrode includes a peripheral gate electrode of a peripheral transistor formed in the peripheral circuit region,
wherein the fin-like structure includes a peripheral fin-like structure which is formed in the peripheral circuit region and which extends, having another height and another width, in a direction intersecting a direction in which the peripheral gate electrode extends, and
wherein the peripheral gate electrode is so formed as to cover a surface of the peripheral fin-like structure.

6. The image pickup device according to claim 5,
wherein the gate electrode includes a pixel gate electrode of a pixel transistor formed in the pixel region,
wherein the fin-like structure includes another pixel fin-like structure which is formed in the pixel region and which extends, having yet another height and yet another width, in a direction intersecting a direction in which the pixel gate electrode extends, and
wherein the pixel gate electrode is so formed as to cover a surface of the above another pixel fin-like structure.

7. The image pickup device according to claim 1,
wherein, in a state where the transfer transistor is turned on, the width of the pixel fin-like structure is set so that a channel may be formed over the entire pixel fin-like structure.

8. The image pickup device according to claim 1,
wherein, with respect to the semiconductor substrate, a micro-lens is installed on a side where the gate electrode is formed.

9. The image pickup device according to claim 1,
wherein, with respect to the semiconductor substrate, a micro-lens is installed on a side opposite to the side where the gate electrode is formed.

10. A method for manufacturing an image pickup device, comprising the steps of:
forming an element formation region including a step of forming a pixel region by forming a separating insulation film over a semiconductor substrate;
forming a gate electrode in the element formation region including a step of forming a transfer gate electrode in the pixel region;
forming a photoelectric conversion part in a first region of the pixel region located on one side across the transfer gate electrode; and
forming a floating diffusion region in a second region of the pixel region located on the other side across the transfer gate electrode,
wherein the step of forming the pixel region includes the steps of:
forming openings being spaced from one another in a region where the transfer gate electrode is formed in the pixel region;
filling the opening with an insulation film; and
forming, by removing a portion of the insulation film ranging from a surface of the insulation film to a position of depth shallower than a bottom of the opening, a fin-like structure which extends, having a width being defined by the spacing and a height being defined by the depth, and which joins the first region with the second region while extending in a direction intersecting a direction in which the transfer gate electrode is to extend,
wherein, in the step of forming the transfer gate electrode, the transfer gate electrode is so formed as to cover a surface of the fin-like structure.

11. The method for manufacturing an image pickup device according to claim 10,
wherein the step of forming the pixel region includes the steps of:
forming a first pixel region corresponding to light of a first wavelength;
forming a second pixel region corresponding to light of a second wavelength shorter than the first wavelength; and
forming a third pixel region corresponding to light of a third wavelength shorter than the second wavelength,
wherein the step of forming the transfer gate electrode includes the steps of:
forming a first transfer gate electrode in the first pixel region;
forming a second transfer gate electrode in the second pixel region; and
forming a third transfer gate in the third pixel region,
wherein, in the step of forming the first pixel region, a first fin-like structure being the fin-like structure having a first depth as a first height is formed by removing a portion of the insulation film ranging from the surface thereof to the first depth shallower than a bottom of the opening,
wherein, in the step of forming the second pixel region, a second fin-like structure being the fin-like structure having a second depth as a second height is formed by removing a portion of the insulation film ranging from the surface thereof to the second depth which is different from the first depth,
wherein, in the step of forming the third pixel region, a third fin-like structure being the fin-like structure having a third depth as a third height is formed by removing a portion of the insulation film ranging from the surface thereof to the third depth which is different from the first depth and the second depth,
wherein, in the step of forming the first transfer gate electrode, the first transfer gate is so formed as to cover the surface of the first fin-like structure,
wherein, in the step of forming the second transfer gate electrode, the second transfer gate is so formed as to cover the surface of the second fin-like structure, and
wherein, in the step of forming the third transfer gate electrode, the third transfer gate is so formed as to cover the surface of the third fin-like structure.

12. The method for manufacturing an image pickup device according to claim 11,
wherein the step of forming the first pixel region, the second pixel region, and the third pixel region, respectively, includes a step of forming a first conductive type region,
wherein the step of forming the photoelectric conversion part includes the steps of:
forming a first photoelectric conversion part by forming a second conductive type first impurity region in the first conductive region of the first pixel region;
forming a second photoelectric conversion part by forming a second conductive type second impurity region in the first conductive type region of the second pixel region; and
forming a third photoelectric conversion part by forming a second conductive type third impurity region in the first conductive type region of the third pixel region, and
wherein, in the step of forming the first photoelectric conversion part, the second photoelectric conversion part and the third photoelectric conversion part, the first impurity region, the second impurity region, and the third impurity region are formed at different positions of depth based on the first height, the second height, and the third height, respectively.

13. The method for manufacturing an image pickup device according to claim 10,
wherein, in the step of forming the openings spaced from one another in the region where the transfer gate electrode is formed in the pixel region, in the fin-like structure having the spacing as the width, the spacing is so set as to allow a channel to be formed over the entire fin-like structure while a voltage being applied to the transfer gate.
